(19) United States
(12) Patent Application Publication
(10) Pub. No.: US 2019/0194580 A1
(43) Pub. Date: Jun. 27, 2019

(54) TREATMENT LIQUID AND METHOD FOR TREATING LAMINATE

(71) Applicant: FUJIFILM Corporation, Tokyo (JP)

(72) Inventor: Tetsuya KAMIMURA, Haibara-gun (JP)

(73) Assignee: FUJIFILM Corporation, Tokyo (JP)

(21) Appl. No.: 16/291,684

(22) Filed: Mar. 4, 2019

Related U.S. Application Data
(63) Continuation of application No. PCT/JP2017/031042, filed on Aug. 30, 2017.

(30) Foreign Application Priority Data
Sep. 29, 2016 (JP) 2016-192210

(51) Int. Cl. C11D 7/08; B08B 3/08; C11D 7/26; C11D 7/36; C11D 7/34; C11D 7/32; C11D 7/10; C11D 7/50; C11D 1/02; C11D 1/04; C11D 3/37; C11D 3/43; C11D 3/04; C11D 3/20; C11D 3/36; C11D 3/34; C11D 3/33; C11D 3/30; C11D 3/28

(52) U.S. Cl. CPC C11D 7/08; H01L 21/02068; C11D 7/265; C11D 7/36; C11D 7/34; C11D 7/3245; C11D 7/261; C11D 7/3209; C11D 7/3281; C11D 7/10; C11D 7/26; C11D 7/5022; C11D 1/02; C11D 1/04; C11D 3/3765; C11D 3/43; C11D 3/042; C11D 3/046; C11D 3/2082; C11D 3/2086; C11D 3/36; C11D 3/3454; C11D 3/33; C11D 3/2058; C11D 3/30; C11D 3/28; C11D 3/20; B08B 3/08

(57) ABSTRACT

A treatment liquid is a treatment liquid for a semiconductor device, which contains a fluorine-containing compound and a water-soluble aromatic compound not having a heterocyclic group but having a benzene ring, and has a pH of 5 or less.

### CROSS-REFERENCE TO RELATED APPLICATIONS

This application is a Continuation of PCT International Application No. PCT/JP2017/031042, filed on Aug. 30, 2017, which claims priority under 35 U.S.C. § 119(a) to Japanese Patent Application No. 2016-192210, filed on Sep. 29, 2016. Each of the above application(s) is hereby expressly incorporated by reference, in its entirety, into the present application.

### BACKGROUND OF THE INVENTION

### 1. Field of the Invention

The present invention relates to a treatment liquid for a semiconductor device and a method for treating a laminate.

### 2. Description of the Related Art

A semiconductor device such as a charge-coupled device (CCD) and a memory is manufactured by forming fine electronic circuit patterns on a substrate using a photolithographic technique. Specific examples of the manufacturing method include a method in which a laminate having a substrate, a metal layer that serves as a wiring material, formed on the substrate, an etching stop layer formed on the metal layer, an interlayer insulating film formed on the etching stop layer, and a metal hard mask formed on the interlayer insulating film is subjected to a dry etching step using the metal hard mask as a mask, and the respective members are etched so as to expose the surface of the metal layer, thereby providing holes passing through the metal hard mask, the interlayer insulating film, and the etching stop layer.

In a laminate which has been subjected to a dry etching step, residues (dry etching residues) of the respective members adhere on at least one of a metal layer or an interlayer insulating film, constituting holes, in some cases. As a result, removal of the residues of the respective members is performed in some cases.

For such removal of the residues, a treatment liquid containing a fluorine-containing compound is used in some cases, and for example, a washing composition containing a fluorine-containing compound, a hexafluoroisopropyl alcohol, and the like is disclosed in JP2015-200830A (claim 1).

### SUMMARY OF THE INVENTION

In the laminate which has been subjected to a dry etching step, a metal hard mask (for example, ZrOx) is present out of a hole region, and therefore, removal of the metal hard mask is required. For such removal of the metal hard mask, wet etching using a treatment liquid containing hydrogen fluoride (HF) described in JP2015-200830A is used in some cases. However, in a case of using a treatment liquid containing hydrogen fluoride, there is a problem that an interlayer insulating film (for example, SiOx) is also etched.

In addition, the treatment liquid is also used for removal of dry etching residues as described above in some cases, in addition to being used as an etching liquid of a metal hard mask. However, in a case where it is intended to remove the dry etching residues of the metal hard mask, there is a problem that the above-mentioned interlayer insulating film is etched.

Therefore, an object of the present invention is to provide a treatment liquid which has excellent removability for a metal hard mask and residues thereof and is capable of suppressing the etching of an insulating film; and a method for treating a laminate.

The present inventors have conducted extensive studies on the objects, and have found that desired effects are obtained by using a treatment liquid having a pH of 5 or less and containing a fluorine-containing compound and a water-soluble aromatic compound not having a heterocyclic group but having a benzene ring, leading to the present invention.

That is, the present inventors have found that the objects can be accomplished by the following configuration.

[1] A treatment liquid for a semiconductor device, comprising:

a fluorine-containing compound; and

a water-soluble aromatic compound not having a heterocyclic group but having a benzene ring,

in which the treatment liquid has a pH of 5 or less.

[2] The treatment liquid as described in [1],

in which a pKa of the water-soluble aromatic compound is 6 or less.

[3] The treatment liquid as described in [1] or [2], further comprising water,

in which a content of water is 50% by mass or more with respect to the total mass of the treatment liquid.

[4] The treatment liquid as described in any one of [1] to [3], wherein the treatment liquid does not comprise an oxidizing agent.

[5] The treatment liquid as described in any one of [1] to [4],

in which the fluorine-containing compound is hydrogen fluoride.

[6] The treatment liquid as described in any one of [1] to [5],

in which the water-soluble aromatic compound has an acidic group.

[7] The treatment liquid as described in any one of [1] to [6],

in which the water-soluble aromatic compound includes at least one selected from the group consisting of phenylphosphonic acid, benzenecarboxylic acid, benzenesulfonic acid, and derivatives thereof.

[8] The treatment liquid as described in any one of [1] to [7],

in which a content of the water-soluble aromatic compound is 0.05% to 10% by mass with respect to the total mass of the treatment liquid.

[9] The treatment liquid as described in any one of [1] to [8],

in which in a case where a content of the fluorine-containing compound and a content of the water-soluble aromatic compound are defined as M1 and M2, respectively, a content ratio M1/M2 is 0.05 to 10.

[10] The treatment liquid as described in any one of [1] to [9],

in which the pH is 2 to 5.

[11] The treatment liquid as described in any one of [1] to [10], further comprising an anionic surfactant.

[12] The treatment liquid as described in any one of [1] to [11], further comprising a corrosion inhibitor.

[13] The treatment liquid as described in any one of [1] to [12], further comprising a boron-containing compound.

[14] The treatment liquid as described in any one of [1] to [13], further comprising an organic solvent.

[15] The treatment liquid as described in any one of [1] to [14], further comprising an anionic polymer.

[16] The treatment liquid as described in [15],

in which a weight-average molecular weight of the anionic polymer is 2,000 to 100,000.

[17] The treatment liquid as described in [15] or [16],

in which the anionic polymer is a polyacrylic acid.

[18] The treatment liquid as described in any one of [1] to [17], further comprising a metal ion.

[19] The treatment liquid as described in [18],

in which the metal ion is a divalent or higher metal ion.

[20] The treatment liquid as described in [18] or [19],

in which the metal ion is at least one selected from the group consisting of an alkaline earth metal ion and an Al ion.

[21] The treatment liquid as described in any one of [18] to [20],

in which the metal ion is at least one selected from the group consisting of a Sr ion, a Ba ion, and an Al ion.

[22] The treatment liquid as described in any one of [1] to [21],

in which the semiconductor device has a laminate for a semiconductor device, the laminate comprising a substrate, a second layer formed on the substrate, and a first layer formed on the second layer,

the second layer includes at least one material selected from the group consisting of SiOx, SiOC, SiN, and SiON, where x is a number represented by 1 to 3, and the first layer is formed of materials other than those of the second layer, and

the treatment liquid is used for a treatment of the laminate.

[23] The treatment liquid as described in [22],

in which the first layer includes at least one material selected from the group consisting of TiN, TiOx, and ZrOx, where x is a number represented by 1 to 3.

[24] The treatment liquid as described in [22] or [23],

in which in a case where a removal rate of the first layer by the treatment liquid and a removal rate of the second layer by the treatment liquid are defined as ER1 and ER2, respectively, a removal rate ratio ER1/ER2 is 0.5 to 1,000.

[25] The treatment liquid as described in any one of [22] to [24],

in which the laminate further comprises a third layer between the substrate and the second layer, and

the third layer is a metal including at least one material selected from the group consisting of W, Co, Cu, and Al.

[26] A method for treating a laminate, comprising a treating step B of subjecting a laminate for a semiconductor device to a treatment, using the treatment liquid as described in any one of [1] to [25], the laminate comprising a substrate, a second layer formed on the substrate, and a first layer formed on the second layer,

in which the first layer includes at least one material selected from the group consisting of TiN, TiOx, and ZrOx, and

the second layer includes at least one material selected from the group consisting of SiOx, SiOC, SiN, and SiON, where x is a number represented by 1 to 3.

[27] The method for treating a laminate as described in [26], further comprising a treatment liquid preparing step A of preparing the treatment liquid before the treating step B.

As shown below, according to the present invention, it is possible to provide a treatment liquid which has excellent removability for a metal hard mask and residues thereof and is capable of suppressing the etching of an insulating film; and a method for treating a laminate.

### BRIEF DESCRIPTION OF THE DRAWINGS

FIG. 1 is a schematic cross-sectional view showing an example of a treatment target of the treatment liquid of an embodiment of the present invention.

### DESCRIPTION OF THE PREFERRED EMBODIMENTS

Hereinbelow, the present invention will be described.

Furthermore, in the present invention, the numerical value ranges shown using “to” mean ranges including the numerical values indicated before and after “to” as the lower limit value and the upper limit value, respectively.

Moreover, in the present invention, a reference to “preparation” is meant to encompass delivering a predetermined material by purchases or the like, in addition to comprising specific materials by synthesis, combination, or the like.

Incidentally, in the present invention, 1 Å (angstrom) corresponds to 0.1 nm.

In addition, in citations for a group (atomic group) in the present invention, in a case where the group (atomic group) is denoted without specifying whether it is substituted or unsubstituted, the group (atomic group) includes both a group (atomic group) having no substituent and a group (atomic group) having a substituent within a range not impairing the effects of the present invention. For example, a “hydrocarbon group” includes not only a hydrocarbon group having no substituent (unsubstituted hydrocarbon group) but also a hydrocarbon group having a substituent (substituted hydrocarbon group). This also applies to the respective compounds.

Moreover, “radiation” in the present invention means, for example, a bright line spectrum of a mercury lamp, far ultraviolet rays typified by excimer laser, extreme ultraviolet rays (EUV light), X-rays, or electron beams. Further, the term “light” in the present invention means actinic rays or radiation. Unless otherwise indicated, the term “exposure” in the present invention includes not only exposure to a bright line spectrum of a mercury lamp, far ultraviolet rays typified by excimer laser, X-rays, EUV light, or the like but also exposure using lithography with particle beams such as electron beams and ion beams.

In addition, in the present invention, “(meth)acrylate” represents both or either of acrylate and methacrylate.

[Treatment Liquid]

The treatment liquid of the embodiment of the present invention is a treatment liquid for a semiconductor device, which contains a fluorine-containing compound and a water-soluble aromatic compound not having a heterocyclic group but having a benzene ring, and has a pH of 5 or less.

The treatment liquid of the embodiment of the present invention has excellent removability for a metal hard mask and residues (etching residues) thereof, and is capable of suppressing the etching of an insulating film. Some of details of a reason therefor are still not clear, but the reason is presumed to be as follows.

In a case of using the treatment liquid of the embodiment of the present invention, the metal hard mask and etching residues thereof are sufficiently removed by the action of the fluorine-containing compound included in the treatment liquid.

Here, the fluorine-containing compound included in the treatment liquid easily causes the etching of the insulating film comprised in the laminate for a semiconductor device, but it is thought that the etching of the insulating film can be suppressed by the action of the water-soluble aromatic compound included in the treatment liquid of the embodiment of the present invention.

A reason therefor is presumed as follows: the water-soluble aromatic compound having a hydrophobic skeleton (an aromatic ring such as a benzene ring) sufficiently adheres onto the insulating film with a hydrophobic surface, and thus, the water-soluble aromatic compound functions as a protective film for the insulating film, thereby suppressing the etching of the insulating film.

Hereinafter, the components which are included or can be included in the treatment liquid of the embodiment of the present invention will be described. Further, in the following description, in a case where “the above-mentioned effects of the present invention” are referred to, the effects encompass both of excellent removability for a metal hard mask and residues (etching residues) thereof and an excellent function of suppressing the etching of the insulating film.

<Fluorine-Containing Compound>

The treatment liquid of the embodiment of the present invention contains a fluorine-containing compound. The fluorine-containing compound comprises a function of removing (dissolving) a metal hard mask and residues thereof.

The fluorine-containing compound is not particularly limited as long as it contains a fluorine atom within the compound, and a known fluorine-containing compound can be used. Among those, as the fluorine-containing compound, those capable of being dissociated in the treatment liquid and discharging fluoride ions are preferable.

Examples of the fluorine-containing compound include hydrogen fluoride (HF), ammonium fluoride, tetramethyl ammonium fluoride, hexafluorophosphoric acid, hexafluorosilicic acid, ammonium hexafluorophosphate, and ammonium hexafluorosilicate.

Furthermore, as a counterion, cations other than ammonium, such as tetramethylammonium, may be used.

From the viewpoint that the function is further exerted, it is preferable that the fluorine-containing compound is hydrogen fluoride.

A content of the fluorine-containing compound in the treatment liquid is preferably 0.01% by mass or more, more preferably 0.1% by mass or more, and still more preferably 1% by mass or more, with respect to the total mass of the treatment liquid. The upper limit is preferably 10% by mass or less, more preferably 5% by mass or less, and still more preferably 2% by mass or less.

By adjusting the content of the fluorine-containing compound to 0.01% by mass or more, the above-mentioned function is further exerted. Further, by adjusting the content of the fluorine-containing compound to 10% by mass or less, corrosion of the insulating film by the treatment liquid can be further suppressed.

Furthermore, the fluorine-containing compound may be used singly or in combination of two or more kinds thereof. In a case where two or more kinds of the fluorine-containing compounds are used in combination, the total content thereof is preferably within the range.

<Water-Soluble Aromatic Compound>

The treatment liquid of the embodiment of the present invention contains a water-soluble aromatic compound not having a heterocyclic group but having a benzene ring.

In the present invention, the water-soluble aromatic compound refers to an aromatic compound having a solubility in water (25° C.) of 3 g/L or more (preferably 5 g/L or more, more preferably 10 g/L or more, and still more preferably 30 g/L or more).

The water-soluble aromatic compound may have various functional groups.

Examples of the functional groups include a carboxyl group, a phosphoric acid group, a phosphonic acid group, a sulfonic acid group, an amino group, and a hydroxyl group.

From the viewpoint that a protective function for an insulating film is further exerted, it is preferable that the water-soluble aromatic compound has an acidic group. Specific examples of the acidic group include a carboxyl group, a phosphoric acid group, a phosphonic acid group, and a sulfonic acid group.

It is preferable that the water-soluble aromatic compound includes at least one selected from the group consisting of phenylphosphonic acid, benzenecarboxylic acid, benzenesulfonic acid, phenol, and derivatives thereof, and from the viewpoint that a protective function for an insulating film is further exerted, it is more preferable that the water-soluble aromatic compound includes at least one selected from the group consisting of phenylphosphonic acid, benzenecarboxylic acid, benzenesulfonic acid, and derivatives thereof.

Examples of the phenylphosphonic acid and derivatives thereof include phenylphosphonic acid and carboxyphenylphosphonic acid.

Examples of the benzenecarboxylic acid and derivatives thereof include benzoic acid, salicylic acid, phthalic acid, anthranilic acid, and dihydroxybenzoic acid, and among these, salicylic acid or phthalic acid is preferable, and phthalic acid is more preferable.

Examples of the benzenesulfonic acid and derivatives thereof include benzenesulfonic acid and p-toluenesulfonic acid, and among these, p-toluenesulfonic acid is preferable.

Examples of the phenol and derivatives thereof include phenol, catechol, resorcinol, hydroquinone, t-butylcatechol, and pyrogallol, and among these, catechol is preferable.

Examples of the water-soluble aromatic compound other than the above compounds include a water-soluble aromatic compound having an amino group, such as xylenediamine.

A pKa (acid dissociation constant) of the water-soluble aromatic compound is preferably 6 or less, more preferably 5 or less, and still more preferably 4 or less. Further, the lower limit value is not particularly limited, but is preferably −3 or more, and more preferably −2 or more.

By adjusting the pKa of the water-soluble aromatic compound to 6 or less, a protective function for the insulating film is further exerted.

A content of the water-soluble aromatic compound in the treatment liquid is preferably 0.05% to 10% by mass, more preferably 0.1% to 10% by mass, and still more preferably 0.5% to 8% by mass, with respect to the total mass of the treatment liquid. In a case where the content of the water-soluble aromatic compound is 0.05% by mass or more, a protective function for an insulating film is further exerted. In a case where the content of the water-soluble aromatic compound is 10% by mass or less, it is possible to suppress the precipitation of the compound over time.

In addition, the water-soluble aromatic compound may be used singly or in combination of two or more kinds thereof. In a case where two or more kinds of the water-soluble aromatic compounds are used in combination, the total content thereof is preferably within the range.

In a case where a content (% by mass) of the fluorine-containing compound and a content (% by mass) of the water-soluble aromatic compound are defined as M1 and M2, respectively, a content ratio M1/M2 is preferably 0.05 to 10, more preferably 0.1 to 5, and still more preferably 0.1 to 1.

By adjusting the content ratio M1/M2 to 0.1 or more, the removability for a metal hard mask and residues thereof is further improved. By adjusting the content ratio M1/M2 to 5 or less, generation of damages of the insulating film can be further suppressed.

<Corrosion Inhibitor>

The treatment liquid of the embodiment of the present invention preferably contains a corrosion inhibitor. The corrosion inhibitor is a compound other than the water-soluble aromatic compound. Further, in the present specification, even in a case where compounds suitable for the definition of the water-soluble aromatic compound are also mentioned below as a corrosion inhibitor, the compounds are intended to be categorized into the water-soluble aromatic compound.

The corrosion inhibitor has a function of suppressing the etching on the metal layer serving as a wiring of a semiconductor device, or the like from by the fluorine-containing compound. The corrosion inhibitor is referred to as an anticorrosive agent in some cases.

The corrosion inhibitor is not particularly limited, but examples thereof include 1,2,4-triazole (TAZ), 5-aminotetrazole (ATA), 5-amino-1,3,4-thiadiazole-2-thiol, 3-amino-1H-1,2,4-triazole, 3,5-diamino-1,2,4-triazole, tolyltriazole, 3-amino-5-mercapto-1,2,4-triazole, 1-amino-1,2,4-triazole, 1-amino-1,2,3-triazole, 1-amino-5-methyl-1,2,3-triazole, 3-mercapto-1,2,4-triazole, 3-isopropyl-1,2,4-triazole, naphthotriazole, 1H-tetrazol-5-acetic acid, 2-mercaptobenzothiazole (2-MBT), 1-phenyl-2-tetrazoline-5-thione, 2-mercaptobenzimidazole (2-MBI), 4-methyl-2-phenylimidazole, 2-mercaptothiazoline, 2,4-diamino-6-methyl-1,3,5-triazine, thiazole, imidazole, benzimidazole, triazine, methyltetrazole, bismuthiol I, 1,3-dimethyl-2-imidazolidinone, 1,5-pentamethylenetetrazole, 1-phenyl-5-mercaptotetrazole, imidazolinethione, 4-methyl-4H-1,2,4-triazole-3-thiol, 5-amino-1,3,4-thiadiazole-2-thiol, benzothiazole, tritolyl phosphate, indazole, adenine, cytosine, guanine, thymine, propanethiol, benzohydroxamic acids, thiourea, 1,1,3,3-tetramethylurea, urea, uric acid, potassium ethylxanthate, glycine, dodecyl phosphonic acid, iminodiacetic acid, citric acid, malonic acid, succinic acid, nitrilotriacetic acid, sulfolane, 2,3,5-trimethylpyrazine, 2-ethyl-3,5-dimethyl pyrazine, quinoxaline, acetylpyrrole, pyridazine, histadine, pyrazine, cysteine, cystine, thiophene, mercaptopyridine N-oxide, thiamine HCl, tetraethyl thiuram disulfide, 2,5-dimercapto-1,3-thiadiazole-ascorbic acid, and ascorbic acid.

It is also preferable that the substituted or unsubstituted benzotriazole is included as the corrosion inhibitor. Suitable examples of the substituted benzotriazole include, but are not limited to, a benzotriazole substituted with an alkyl group, an aryl group, a halogen group, an amino group, a nitro group, an alkoxy group, or a hydroxyl group. Other examples of the substituted benzotriazole include benzotriazoles substituted with one or more aryl groups (for example, a phenyl group) or heteroaryl groups.

Examples of the benzotriazole which is suitable for use as the corrosion inhibitor include, but are not limited to, benzotriazole (BTA), 5-aminotetrazole, 1-hydroxybenzotriazole, 5-phenylthiol-benzotriazole, 5-chlorobenzotriazole, 4-chlorobenzotriazole, 5-bromobenzotriazole, 4-bromobenzotriazole, 5-fluorobenzotriazole, 4-fluorobenzotriazole, naphthotriazole, tolyltriazole, 5-phenyl-benzotriazole, 5-nitrobenzotriazole, 4-nitrobenzotriazole, 3-amino-5-mercapto-1,2,4-triazole, 2-(5-amino-pentyl)-benzotriazole, 1-amino-benzotriazole, 5-methyl-1H-benzotriazole (5-MBTA), 4-methylbenzotriazole, 4-ethylbenzotriazole, 5-ethylbenzotriazole, 4-propylbenzotriazole, 5-propylbenzotriazole, 4-isopropylbenzotriazole, 5-isopropylbenzotriazole, 4-n-butylbenzotriazole, 5-n-butylbenzotriazole, 4-isobutylbenzotriazole, 5-isobutylbenzotriazole, 4-pentylbenzotriazole, 5-pentylbenzotriazole, 4-hexylbenzotriazole, 5-hexylbenzotriazole, 5-methoxybenzotriazole, 1-[N,N-bis(2-ethylhexyl)aminomethyl]-benzotriazole, 5-t-butylbenzotriazole, 5-(1′,1′-dimethylpropyl)-benzotriazole, 5-(1′,1′,3′-trimethylbutyl)benzotriazole, 5-n-octylbenzotriazole, and 5-(1′,1′,3′,3′-tetramethylbutyl)benzotriazole.

In addition, as the benzotriazole, 2,2′-{[(4-methyl-1H-benzotriazol-1-yl)methyl]imino}bisethanol, 2,2′-{[(5-methyl-1H-benzotriazol-1-yl)methyl]imino}bisethanol, 2,2′-{[(4-methyl-1H-benzotriazol-1-yl)methyl]imino}bisethane, 2,2′-{[(4-methyl-1H-benzotriazol-1-yl)methyl]imino}bispropane, N,N-bis(2-ethylhexyl)-(4 or 5)-methyl-1H-benzotriazole-1-methylamine, or the like can also be used.

From the viewpoint of further improving an anticorrosion property, it is preferable that at least one selected from the group consisting of a compound represented by Formula (A), a compound represented by Formula (C), and a substituted or unsubstituted tetrazole is used as the corrosion inhibitor.

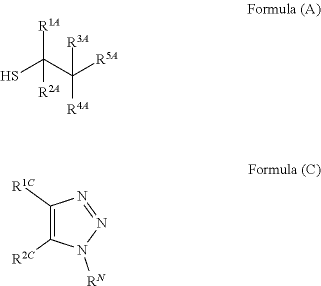

In Formula (A), R^{1A} to R^{5A} each independently represent a hydrogen atom, a substituted or unsubstituted hydrocarbon group, a hydroxyl group, a carboxyl group, or a substituted or unsubstituted amino group, provided that at least one group selected from a hydroxyl group, a carboxyl group, or a substituted or unsubstituted amino group is included in the structure.

In Formula (C), R^{1C}, R^{2C}, and R^{N} each independently represent a hydrogen atom or a substituted or unsubstituted hydrocarbon group. Further, R^{1C} and R^{2C} may be bonded to each other to form a ring.

In Formula (A), as the hydrocarbon represented by R^{1A} to R^{5A}, an alkyl group (preferably having 1 to 12 carbon atoms, more preferably having 1 to 6 carbon atoms, and particularly preferably having 1 to 3 carbon atoms), an alkenyl group (preferably having 2 to 12 carbon atoms, and more preferably having 2 to 6 carbon atoms), an alkynyl group (preferably having 2 to 12 carbon atoms, and more preferably having 2 to 6 carbon atoms), an aryl group (preferably having 6 to 22 carbon atoms, more preferably having 6 to 14 carbon atoms, and particularly preferably having 6 to 10 carbon atoms), and an aralkyl group (preferably having 7 to 23 carbon atoms, more preferably having 7 to 15 carbon atoms, and particularly preferably having 7 to 11 carbon atoms).

Incidentally, examples of the substituent include a hydroxyl group, a carboxyl group, and a substituted or unsubstituted amino group (as the substituent, an alkyl group having 1 to 6 carbon atoms is preferable, and an alkyl group having 1 to 3 carbon atoms is more preferable).

In addition, in Formula (A), at least one group selected from a hydroxyl group, a carboxyl group, or a substituted or unsubstituted amino group (as the substituent, an alkyl group having 1 to 6 carbon atoms is preferable, and an alkyl group having 1 to 3 carbon atoms is more preferable) is included in the structure.

In Formula (A), examples of the substituted or unsubstituted hydrocarbon group represented by R^{1A} to R^{5A} include a hydroxyl group, a carboxyl group, and a hydrocarbon group having 1 to 6 carbon atoms, substituted with an amino group.

Examples of the compound represented by Formula (A) include 1-thioglycerol, L-cysteine, and thiomalic acid.

In Formula (C), the hydrocarbon group represented by R^{1C}, R^{2C}, and R^{N} or the substituent each has the same definitions as those of the hydrocarbon group represented by R^{1A} to R^{5A} or the substituent in Formula (A). Examples of the substituted or unsubstituted hydrocarbon group represented by R^{1C}, R^{2C}, and R^{N} include a hydrocarbon group having 1 to 6 carbon atoms, such as a methyl group, an ethyl group, a propyl group, and a butyl group.

Furthermore, R^{1C} and R^{2C} may be bonded to each other to form a ring, and examples of the ring include a benzene ring. In a case where R^{1C} and R^{2C} are bonded to each other to form a ring, the ring may further have a substituent (for example, a hydrocarbon group having 1 to 5 carbon atoms).

Examples of the compound represented by Formula (C) include 1H-1,2,3-triazole, benzotriazole, and 5-methyl-1H-benzotriazole.

Examples of the substituted or unsubstituted tetrazole include an unsubstituted tetrazole, and a tetrazole having a hydroxyl group, a carboxyl group, or a substituted or unsubstituted amino group (as the substituent, an alkyl group having 1 to 6 carbon atoms is preferable, and an alkyl group having 1 to 3 carbon atoms is more preferable) as a substituent.

A content of the corrosion inhibitor in the treatment liquid is preferably 0.01% to 5% by mass, more preferably 0.05% to 5% by mass, and still more preferably 0.1% to 3% by mass, with respect to the total mass of the treatment liquid.

The corrosion inhibitor may be used singly or in combination of two or more kinds thereof. In a case where two or more kinds of the corrosion inhibitors are used in combination, the total amount thereof is preferably within the above-mentioned range.

<Boron-Containing Compound>

The treatment liquid of the embodiment of the present invention preferably contains a boron-containing compound. The boron-containing compound has a function of suppressing the etching on the metal layer (in particular, Co and Cu) by the fluorine-containing compound.

Examples of the boron-containing compound include boric acid, monophenyl borate, triphenyl borate, boron oxide, boron chloride, and methyl borate, and from the viewpoint that the function is further exerted, boric acid or monophenyl borate is preferable, and boric acid is more preferable.

A content of the boron-containing compound in the treatment liquid is preferably 0.01% to 5% by mass, more preferably 0.05% to 5% by mass, and still more preferably 0.1% to 3% by mass, with respect to the total mass of the treatment liquid.

By adjusting the content of the boron-containing compound to 0.01% by mass or more, the function is further exerted.

The boron-containing compound may be used singly or in combination of two or more kinds thereof. In a case where two or more kinds of the boron-containing compounds are used in combination, the total amount thereof is preferably within the above-mentioned range.

<Metal Ion>

The treatment liquid of the embodiment of the present invention preferably contains a metal ion. The metal ion has a function of suppressing the etching on the metal layer (in particular, Al) and the etching stop layer (in particular, AlOx, where x is 1 to 3) by the fluorine-containing compound.

Specifically, the metal ion is ionically bonded to a fluorine-containing compound (F) in the treatment liquid adhering onto the surface of the metal layer (in particular, Al) and the etching stop layer (in particular, AlOx), and thus, sufficiently functions as a protective layer for the surface of the metal layer and the etching stop layer. As a result, it is possible to suppress the fluorine-containing compound from being freshly supplied to the surface of the metal layer and the etching stop layer, the etching of the metal layer and etching stop layer by the fluorine-containing compound can be suppressed.

From the viewpoint that the above-mentioned function is further exerted, as the metal ion, a divalent or higher metal ion is preferable, at least one selected from the group consisting of an alkaline earth metal ion and an Al ion is more preferable, and at least one selected from the group consisting of a Sr ion, a Ba ion, and an Al ion is still more preferable.

A content of the metal ion in the treatment liquid is preferably 0.0005% to 2% by mass, more preferably 0.001% to 1.5% by mass, and still more preferably 0.01% to 1% by mass, with respect to the total mass of the treatment liquid. By adjusting the content of the metal ion to be within the range, the above-mentioned function is further exerted.

The metal ion may be used singly or in combination of two or more kinds thereof. In a case where two or more kinds of the metal ions are used in combination, the total amount thereof is preferably within the above-mentioned range.

Here, the metal ion in the form of a metal salt may be blended into the treatment liquid. That is, in this case, the treatment liquid of the embodiment of the present invention is formed by blending a metal salt having the metal ion thereinto. In this case, the blend amount of the metal salt in the treatment liquid is preferably 0.001% to 3% by mass, more preferably 0.01% to 3% by mass, still more preferably 0.05% to 3% by mass, and even still more preferably 0.1% to 3% by mass, with respect to the total mass of the treatment liquid. By adjusting the content of the metal ion to be within the range, the above-mentioned function is further exerted.

<Anionic Polymer>

The treatment liquid of the embodiment of the present invention preferably contains an anionic polymer. The anionic polymer has a function of suppressing the etching on the metal layer (in particular, Al) and the etching stop layer (in particular, AlOx, where x is 1 to 3) by the fluorine-containing compound. In particular, in a case of using a combination of the anionic polymer and the metal ion, the function of the respective components acts synergistically, and thus, the function is more remarkably exerted.

Specifically, as described above, the metal ion is ionically bonded to the fluorine-containing compound (F) in the treatment liquid adhering onto the surface of the metal layer (in particular, Al) and the etching stop layer (in particular, AlOx), and this metal ion is ionically bonded to the anionic polymer. That is, since two layers of the layer of the metal ion and the layer of the anionic polymer are formed on the metal layer and the etching stop layer, the etching on the metal layer and the etching stop layer by the fluorine-containing compound can be suppressed more effectively.

The anionic polymer is preferably a polymer having an anionic group or a salt thereof. Examples of the anionic group include a carboxyl group, a sulfonic acid group, and a phosphoric acid group, and the anionic group is preferably a carboxyl group.

Specific examples of the anionic polymer include polyacrylic acid, polymethacrylic acid, polyitaconic acid, polymaleic acid, polyfumaric acid, polyaspartic acid, polyglutamic acid, polystyrene sulfonic acid, polyacrylamide methylpropane sulfonic acid, and polyphosphoric acid, and salts thereof, and from the viewpoint that the function is further exerted, polyacrylic acid, polymethacrylic acid, polystyrenesulfonic acid, and polyphosphoric acid, and salts thereof are preferable, polyacrylic acid and a salt thereof are more preferable, and polyacrylic acid is still more preferable.

The weight-average molecular weight of the anionic polymers is preferably 500 to 150,000, more preferably 2,000 to 100,000, and still more preferably 3,000 to 50,000. By adjusting the weight-average molecular weight of the anionic polymers to be within the range, the function is further exerted.

The weight-average molecular weight (Mw) of the respective components in the present invention is determined by a value in terms of standard polystyrene measured by a gel permeation chromatography (GPC) method unless otherwise specified. Specifically, the measurement of the weight-average molecular weight by a GPC method can be performed by dissolving the respective components in tetrahydrofuran (THF), and using high-performance GPC (HLC-8220 GPC, manufactured by Tosoh Corporation), TSKgel Super HZ4000 (4.6 mm I.D.×15 cm, manufactured by Tosoh Corporation) as a column, and THF as an eluent.

A content of the anionic polymer in the treatment liquid is preferably 0.01% to 10% by mass, more preferably 0.05% to 5% by mass, and still more preferably 0.1% to 5% by mass, with respect to the total mass of the treatment liquid. By adjusting the content of the anionic polymer to be within the range, the above-mentioned function is further exerted.

The anionic polymer may be used singly or in combination of two or more kinds thereof. In a case where two or more kinds of the anionic polymers are used in combination, the total amount thereof is preferably within the above-mentioned range.

<Organic Solvent>

The treatment liquid of the embodiment of the present invention preferably contains an organic solvent. By incorporation of the organic solvent, the anticorrosion effect of an insulating film or the like can be further improved.

As the organic solvent, all of known organic solvents can be used, but a hydrophilic organic solvent is preferable. The hydrophilic organic solvent means an organic solvent which can be uniformly mixed with water at any ratio.

Specific examples of the hydrophilic organic solvent include a water-soluble alcohol-based solvent, a water-soluble ketone-based solvent, a water-soluble ester-based solvent, a water-soluble ether-based solvent (for example, glycol diether), a sulfone-based solvent, a sulfoxide-based solvent, a nitrile-based solvent, and an amide-based solvent, and in order to obtain desired effects of the present application, any of those solvents can be used.

Examples of the water-soluble alcohol-based solvent include an alkanediol (including, for example, alkylene glycol), an alkoxyalcohol (including, for example, glycol monoether), a saturated aliphatic monohydric alcohol, an unsaturated non-aromatic monohydric alcohol, and a low-molecular-weight alcohol including a ring structure.

Examples of the alkanediol include glycol, 2-methyl-1,3-propanediol, 1,3-propanediol, 2,2-dimethyl-1,3-propanediol, 1,4-butanediol, 1,3-butanediol, 1,2-butanediol, 2,3-butanediol, pinacol, and alkylene glycol.

Examples of the alkylene glycol include ethylene glycol, propylene glycol, hexylene glycol, diethylene glycol, dipropylene glycol, triethylene glycol, and tetraethylene glycol.

Examples of the alkoxyalcohol include 3-methoxy-3-methyl-1-butanol, 3-methoxy-1-butanol, 1-methoxy-2-butanol, and glycol monoether.

Examples of the glycol monoether include ethylene glycol monomethyl ether, ethylene glycol monoethyl ether, ethylene glycol mono-n-propyl ether, ethylene glycol monoisopropyl ether, ethylene glycol mono-n-butyl ether, diethylene glycol monomethyl ether, diethylene glycol monoethyl ether, diethylene glycol monobutyl ether, triethylene glycol monomethyl ether, triethylene glycol monoethyl ether, triethylene glycol monobutyl ether, 1-methoxy-2-propanol, 2-methoxy-1-propanol, 1-ethoxy-2-propanol, 2-ethoxy-1-propanol, propylene glycol mono-n-propyl ether, dipropylene glycol monomethyl ether, dipropylene glycol monoethyl ether, dipropylene glycol mono-n-propyl ether, tripropylene glycol monoethyl ether, tripropylene glycol monomethyl ether, ethylene glycol monobenzyl ether, and diethylene glycol monobenzyl ether.

Examples of the saturated aliphatic monohydric alcohol include methanol, ethanol, n-propyl alcohol, isopropyl alcohol, 1-butanol, 2-butanol, isobutyl alcohol, tert-butyl alcohol, 2-pentanol, t-pentyl alcohol, and 1-hexanol.

Examples of the unsaturated non-aromatic monohydric alcohol include allyl alcohol, propargyl alcohol, 2-butenyl alcohol, 3-butenyl alcohol, and 4-penten-2-ol.

Examples of the low-molecular-weight alcohol including a ring structure include tetrahydrofurfuryl alcohol, furfuryl alcohol, and 1,3-cyclopentanediol.

Examples of the water-soluble ketone-based solvent include acetone, propanone, cyclobutanone, cyclopentanone, cyclohexanone, diacetone alcohol, 2-butanone, 5-hexanedione, 1,4-cyclohexanedione, 3-hydroxyacetophenone, 1,3-cyclohexanedione, and cyclohexanone.

Examples of the water-soluble ester-based solvent include ethyl acetate, glycol monoesters such as ethylene glycol monoacetate and diethyleneglycol monoacetate, and glycol monoether monoesters such as propylene glycol monomethyl ether acetate, ethylene glycol monomethyl ether acetate, propylene glycol monoethyl ether acetate, and ethylene glycol monoethyl ether acetate.

Among those, ethylene glycol monobutyl ether, tri(propylene glycol) methyl ether, and diethylene glycol monoethyl ether are preferable.

Examples of the sulfone-based solvent include sulfolane, 3-methyl sulfolane, and 2,4-dimethyl sulfolane.

Examples of the sulfoxide-based solvent include dimethyl sulfoxide.

Examples of the nitrile-based solvent include acetonitrile.

Examples of the amide-based solvent include N,N-dimethylformamide, 1-methyl-2-pyrrolidone, 2-pyrrolidinone, 1,3-dimethyl-2-imidazolidinone, ε-caprolactam, formamide, N-methylformamide, acetamide, N-methylacetamide, N,N-dimethylacetamide, N-methylpropaneamide, and hexamethylphosphoric triamide.

Among the hydrophilic organic solvents, from the viewpoint of further improving the anticorrosion effect, the water-soluble alcohol-based solvent, the sulfone-based solvent, the amide-based solvent, and the sulfoxide-based solvent are preferable, the water-soluble alcohol-based solvent and the sulfoxide-based solvent are more preferable, and the water-soluble alcohol-based solvent is still more preferable.

A content of the organic solvent in the treatment liquid is preferably 1% to 50% by mass, more preferably 5% to 30% by mass, and still more preferably 5% to 20% by mass, with respect to the total mass of the treatment liquid.

In particular, by adjusting the content of the organic solvent to a range of 5% to 30% by mass, the washing performance for etching residues and anticorrosion properties (corrosion performance) which will be described later for the second layer and the third layer are further improved.

The organic solvent may be used singly or in combination of two or more kinds thereof. In a case where two or more kinds of the organic solvents are used in combination, the total amount thereof is preferably within the above-mentioned range.

As the organic solvent, a high-purity organic solvent having a reduced content of the metal ions is preferably used, and the high-purity organic solvent which has been further purified is more preferably used.

The purification method is not particularly limited, but a known method such as filtration, ion exchange, distillation, adsorption purification, recrystallization, reprecipitation, sublimation, and purification using a column is used, and these methods can also be combined to be applied.

The organic solvent having a reduced content of the metal ions can be used in each of the embodiments of the present invention, and can also be suitably used, for example, in a device for the manufacture or production of a kit or a concentrate which will be described later, applications for washing a container, or the like.

<Water>

It is preferable that the treatment liquid of the embodiment of the present invention further contains water.

The water is not particularly limited, but ultrapure water used for the manufacture of a semiconductor is preferably used, and water obtained by further purifying the ultrapure water to reduce the amount of inorganic anions, metal ions, and the like is more preferably used. The purification method is not particularly limited, but purification using a filtering film or an ion-exchange membrane, or purification using distillation is preferable. In addition, it is preferable that the purification is performed, for example, by the method described in JP2007-254168A.

A content of the water in the treatment liquid is preferably 50% by mass or more, more preferably 50% to 99% by mass, and still more preferably 60% to 95% by mass, with respect to the total mass of the treatment liquid. In a case where the content of water is 50% by mass or more, the removability for a metal hard mask and residues thereof is further improved.

<Anionic Surfactant>

The treatment liquid of the embodiment of the present invention preferably contains an anionic surfactant. The anionic surfactant has a function of suppressing the etching on the metal layer (in particular, Co and Cu) by the fluorine-containing compound.

Examples of the anionic surfactant include a coconut fatty acid salt, a castor sulfated oil salt, a lauryl sulfate salt, a polyoxyalkylene allyl phenyl ether sulfate salt, alkyl benzene sulfonate, alkyl benzene sulfonate, alkyl diphenyl ether disulfonate, an alkylnaphthalene sulfonate salt, a dialkyl sulfosuccinate salt, isopropyl phosphate, a polyoxyethylene alkyl ether phosphate salt, and a polyoxyethylene allyl phenyl ether phosphate salt.

A content of the anionic surfactant in the treatment liquid is preferably 0.001% to 1% by mass, more preferably 0.001% to 0.2% by mass, and still more preferably 0.003% to 0.2% by mass, with respect to the total mass of the treatment liquid.

By adjusting the content of the anionic surfactant to be within the range, the function is exerted and the etching property of the metal hard mask is further improved.

The anionic surfactant may be used singly or in combination of two or more kinds thereof. In a case where two or more kinds of the anionic surfactants are used in combination, the total amount thereof is preferably within the above-mentioned range.

<Oxidizing Agent>

It is preferable that the treatment liquid of the embodiment of the present invention substantially does not contain an oxidizing agent. By not incorporating the oxidizing agent, an ability to suppress corrosion damages for a metal is further improved.

A description of “not substantially containing an oxidizing agent” specifically means that the content of the oxidizing agent in the treatment liquid is 1% by mass or less, and the content is preferably 0.5% by mass or less, more preferably 0.3% by mass or less, and still more preferably 0% by mass.

Specific examples of the oxidizing agent include nitric acid and hydrogen peroxide, and it is more preferable that the treatment liquid of the embodiment of the present invention substantially does not contain nitric acid.

<Other Additives>

The treatment liquid of the embodiment of the present invention may contain additives other than the above-mentioned components. Examples of such other additives include a chelating agent and a pH adjuster.

(Chelating Agent)

The chelating agent is chelated with an oxidized metal included in the residues. Thus, the recyclability of the treatment liquid is improved by the addition of the chelating agent.

The chelating agent is not particularly limited, but is preferably a polyaminopolycarboxylic acid.

The polyaminopolycarboxylic acid is a compound having a plurality of amino groups and a plurality of carboxylic acid groups, and examples thereof include a monoalkylenepolyamine polycarboxylic acid, a polyalkylenepolyamine polycarboxylic acid, a polyaminoalkane polycarboxylic acid, a polyaminoalkanol polycarboxylic acid, and a hydroxyalkyl ether polyamine polycarboxylic acid.

Suitable examples of the chelating agent of the polyaminopolycarboxylic acid include butylenediaminetetraacetic acid, diethylenetriaminepentaacetic acid (DTPA), ethylenediaminetetrapropionic acid, triethylenetetraaminehexaacetic acid, 1,3-diamino-2-hydroxypropane-N,N,N′,N′-tetraacetic acid, propylenediaminetetraacetic acid, ethylenediaminetetraacetic acid (EDTA), trans-1,2-diaminocyclohexanetetraacetic acid, ethylenediaminediacetic acid, ethylenediaminedipropionic acid, 1,6-hexamethylene-diamine-N,N,N′,N′-tetraacetic acid, N,N-bis(2-hydroxybenzyl)ethylenediamine-N,N-diacetic acid, diaminopropanetetraacetic acid, 1,4,7,10-tetraazacyclododecane-tetraacetic acid, diaminopropanoltetraacetic acid, and (hydroxyethyl)ethylenediaminetriacetic acid. Among those, diethylenetriamine pentaacetic acid (DTPA), ethylenediamine tetraacetic acid (EDTA), and trans-1,2-diaminocyclohexane tetraacetic acid are preferable.

In a case where the treatment liquid contains a chelating agent, the content of the chelating agent in the treatment liquid is preferably 0.01% to 5% by mass, and more preferably 0.01% to 3% by mass, with respect to the total mass of the treatment liquid.

The chelating agent may be used singly or in combination of two or more kinds thereof. In a case where two or more kinds of the chelating agents are used in combination, the total amount thereof is preferably within the above-mentioned range.

(pH Adjuster)

The treatment liquid of the embodiment of the present invention may contain a pH adjuster. Further, in a case where the above-mentioned components which are included or can be included in the treatment liquid overlap the specific examples of the pH adjuster which will be described later, the overlapping components may comprise the above-mentioned function together with the function as a pH adjuster.

As the pH adjuster, quaternary ammonium salts such as choline, hydroxide alkali or alkaline earth salts such as potassium hydroxide, or amino compounds such as 2-aminoethanol and guanidine can be used in order to raise the pH. Although not being limited, it is generally preferable that the pH adjuster does not include a metal ion, and examples thereof include ammonium hydroxide, choline compounds, monoamines, imines (for example, 1,8-diazabicyclo[5.4.0]undecan-7-ne (diazabicycloundecene) and 1,5-diazabicyclo[4.3.0]non-5-ene), 1,4-diazabicyclo[2.2.2]octane, guanidine salts (for example, guanidine carbonate), hydroxylamine, and hydroxylamine salts, any of which can also be used in order to obtain the desired effects of the present application. Among those, ammonium hydroxide, imines (for example, 1,8-diazabicyclo[5.4.0]undecan-7-ene, 1,5-diazabicyclo[4.3.0]non-5-ene), hydroxylamine, or hydroxylamine salts are preferable from the viewpoint of noticeably obtaining the desired effects of the present application.

Examples of the pH adjuster so as to lower the pH include inorganic acids, and organic acids such as a carboxylic acid and an organic sulfuric acid. Specific examples of the inorganic acid include hydrochloric acid, sulfuric acid, hydrofluoric acid, carbonic acid, hypophosphorous acid, phosphorous acid, and phosphoric acid. Specific examples of the carboxylic acid include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, glutaric acid, adipic acid, pimelic acid, maleic acid, phthalic acid, malic acid, tartaric acid, lactic acid, diglycolic acid, 2-furancarboxylic acid, 2,5-furandicarboxylic acid, 3-furancarboxylic acid, 2-tetrahydrofurancarboxylic acid, methoxyacetic acid, methoxyphenylacetic acid, and phenoxyacetic acid. Specific examples of the organic sulfuric acid include methanesulfonic acid, ethanesulfonic acid, and isethionic acid.

The pH adjusters may be used singly or appropriate in combination of two or more kinds thereof.

The content of the pH adjuster is not particularly limited, and for example, the pH of the treatment liquid may be appropriately determined so as to be within the above-mentioned range.

In addition, examples of such other additives include a defoamer, a rust inhibitor, and a preservative.

<Coarse Particles>

It is preferable that the treatment liquid of the embodiment of the present invention substantially does not include coarse particles.

The coarse particles refer to particles having a diameter of 0.2 μm or more, for example, in a case of considering the shapes of the particles as spheres. Further, the expression, substantially not including coarse particles, indicates that the number of particles in a diameter of 0.2 μm or more in 1 mL of the treatment liquid in a case where the treatment liquid is measured using a commercially available measuring device in a light scattering type in-liquid particle measurement system is 10 or less.

Furthermore, the coarse particles included in the treatment liquid are particles of dusts, organic solids, inorganic solids, or the like which are included as impurities in raw materials, or particles of dusts, organic solids, inorganic solids, or the like which are incorporated as a contaminant during the preparation of a treatment liquid, and correspond to the particles which are not ultimately dissolved in the treatment liquid and present as particles.

The amount of the coarse particles present in the treatment liquid can be measured in a liquid phase using a commercially available measuring device in a light scattering type in-liquid particle measurement system with a laser as a light source.

Examples of a method for removing the coarse particles include a treatment such as filtering which will be described later.

<Applications>

The treatment liquid of the embodiment of the present invention is a treatment liquid for a semiconductor device. In the present invention, the expression, “for a semiconductor device” means a use in the manufacture of a semiconductor device. The treatment liquid of the embodiment of the present invention can also be used in any steps for manufacturing a semiconductor device, in addition to removing a metal hard mask and removing etching residues.

For example, the treatment liquid may be used a pre-wet liquid, a solution (for example, a removing liquid and a peeling liquid) used for the removal of a permanent film (for example, a color filter, a transparent insulating film, and a resin-made lens) or the like from a semiconductor substrate; a post chemical mechanical polishing (pCMP) washing liquid; or the like. In addition, the semiconductor substrate after the removal of the permanent film is employed again in the use of a semiconductor device in some cases, and therefore, the removal of the permanent film is included in the step of manufacturing a semiconductor device.

It is preferable that the treatment liquid of the embodiment of the present invention is used for a treatment of a laminate for a semiconductor device in a view that the above-mentioned effects of the present invention are further exerted. Here, the laminate comprises a substrate, a second layer formed on the substrate, and a first layer formed on the second layer. Further, the second layer is formed of materials including SiOx, SiOC, SiN, and SiON, and the first layer is formed of materials other than those of the second layer.

Moreover, the first layer preferably includes at least one material of TiN, TiOx, or ZrOx. Further, the first layer is preferably a metal hard mask.

The second layer is preferably an interlayer insulating film.

In addition, it is preferable that the laminate comprises a third layer between the substrate and the second layer, and the third layer is a metal including at least one material selected from the group consisting of W, Co, Cu, and Al. The third layer is preferably a metal layer (wiring).

The substrate, the first layer, the second layer, and the third layer will be described in detail in “Method for Treating Laminate” which will be described later.

In a case where a removal rate of the first layer by the treatment liquid of the embodiment of the present invention and a removal rate of the second layer by the treatment liquid of the embodiment of the present invention are defined as ER1 and ER2, respectively, a removal rate ratio ER1/ER2 is preferably 0.5 to 1,000, more preferably 0.8 to 800, and still more preferably 1 to 500.

By adjusting the removal rate ratio ER1/ER2 to be within the range, the above-mentioned effects of the present invention are further exerted.

<Physical Properties or the Like of Treatment Liquid>

Selection of the pH is very crucial in the treatment liquid of the embodiment of the present invention. The pH of the treatment liquid of the embodiment of the present invention is 5 or less, preferably 1 to 5, more preferably 2 to 5, and still more preferably 2 to 4. By adjusting the pH of the treatment liquid to 5 or less as described above, the fluorine-containing compound functions well and the removability for the metal hard mask and residues thereof is improved.

The pH of the treatment liquid can be measured using a known pH meter.

[Kit and Concentrate]

The treatment liquid of the embodiment of the present invention may be used in the form of a kit having raw materials thereof divided into a plurality of parts.

In addition, the treatment liquid may be prepared as a concentrate. In this case, it can be used after being diluted with water and/or an organic solvent at the time of use.

[Container (Housing Container)]

The treatment liquid of the embodiment of the present invention can be filled in any container as long as the container does not have any problem such as corrosion properties irrespective of whether the treatment liquid is a kit or a concentrate, transported, and used. As for the container, as a container used in semiconductor applications, a container which has high cleanliness in the container and less elution of impurities is preferable. Examples of the usable container include, but are not limited to, “CLEAN BOTTLE” series (manufactured by Aicello Chemical Co., Ltd.) and “PURE BOTTLE” (manufactured by Kodama Plastics Co., Ltd.). The inner wall of the container is preferably formed of one or more resins selected from the group consisting of a polyethylene resin, a polypropylene resin, and a polyethylene-polypropylene resin, other resins, and a metal which has been antirust and metal elution preventing treatments, such as stainless steel, Hastelloy, Inconel, and Monel.

As such other resins, a fluorine-based resin (perfluoro resin) can be preferably used. In this manner, by using a container having an inner wall formed of a fluorine-based resin, occurrence of a problem of elution of ethylene or propylene oligomers can be suppressed, as compared with a case of using a container having an inner wall formed of a polyethylene resin, a polypropylene resin, or a polyethylene-polypropylene resin.

Specific examples of such a container having an inner wall which is a fluorine-based resin include a FluoroPurePFA composite drum manufactured by Entegris Inc. Further, the containers described in page 4 of JP1991-502677A (JP-H03-502677A), page 3 of WO2004/016526A, pages 9 and 16 of WO99/046309A, or the like can also be used.

Moreover, for the inner wall of the container, the quartz and the electropolished metal material (that is, the metal material which has been completely electropolished) are also preferably used, in addition to the above-mentioned fluorine-based resin.

The metal material used in the production of the electropolished metal material is preferably a metal material which contains at least one selected from the group consisting of chromium and nickel, and has a total content of chromium and nickel of more than 25% by mass with respect to the total mass of the metal material. Examples of the metal material include stainless steel and a nickel-chromium alloy.

The total content of chromium and nickel in the metal material is preferably 25% by mass or more, and more preferably 30% by mass or more, with respect to the total mass of the metal material.

In addition, the upper limit value of the total content of chromium and nickel in the metal material is not particularly limited, but in general, it is preferably 90% by mass or less.

The stainless steel is not particularly limited, and known stainless steel can be used. Among those, an alloy containing 8% by mass or more of nickel is preferable, and austenitic stainless steel containing 8% by mass or more of nickel is more preferable. Examples of the austenitic stainless steel include Steel Use Stainless (SUS) 304 (Ni content of 8% by mass, Cr content of 18% by mass), SUS 304L (Ni content of 9% by mass, Cr content of 18% by mass), SUS 316 (Ni content of 10% by mass, Cr content of 16% by mass), and SUS 316L (Ni content of 12% by mass, Cr content of 16% by mass).

The nickel-chromium alloy is not particularly limited and a known nickel-chromium alloy can be used. Among those, a nickel-chromium alloy having a nickel content of 40% to 75% by mass and a chromium content of 1% to 30% by mass is preferable.

Examples of the nickel-chromium alloy include Hastelloy (trade name, hereinafter, the same shall apply), Monel (trade name, hereinafter, the same shall apply), and Inconel (trade name, hereinafter, the same shall apply). More specific examples thereof include Hastelloy C-276 (Ni content of 63% by mass, Cr content of 16% by mass), HastelloyC (Ni content of 60% by mass, Cr content of 17% by mass), and Hastelloy C-22 (Ni content of 61% by mass, Cr content of 22% by mass).

In addition, the nickel-chromium alloy may further contain boron, silicon, tungsten, molybdenum, copper, cobalt, or the like, as desired, in addition to the above-mentioned alloys.

The method of electropolishing the metal material is not particularly limited, and known methods can be used. For example, the methods described in paragraphs <0011> to <0014> of JP2015-227501A, paragraphs <0036> to <0042> of JP2008-264929A, or the like can be used.

It is presumed that the metal material has a larger content of chromium in the passivation layer on the surface than the content of chromium in the parent phase by electropolishing the metal material. As a result, it is presumed that since it is difficult for the metal elements to flow into the treatment liquid from the inner wall coated with the electropolished metal material, a chemical solution for a semiconductor having a small amount of specific metal elements such as a Ca atom, a Fe atom, and a Na atom can be obtained.

In addition, it is preferable that the metal material is buffed. The buffing method is not particularly limited, and known methods can be used. The size of the abrasive grain used to finish the buffing is not particularly limited, but is preferably #400 or less in view that the unevenness of the surface of the metal material is likely to be smaller.

Incidentally, buffing is preferably performed before the electropolishing.

In addition, the metal material may be subjected to a treatment including one of buffing, acid washing, magnetic fluid polishing, and the like or a combination of two or more thereof in a plurality of steps that are performed by changing the number of a size or the like of the abrasive grains.

In the present invention, a body having the container and the treatment liquid housed in this container is referred to as a treatment liquid housing body in some cases.

For the container, it is preferable to wash the inside of the container before filling. The liquid may be appropriately selected depending on the application, but as long as the liquid is the treatment liquid of the embodiment of the present invention as it is, a dilution of the treatment liquid of the embodiment of the present invention, or a liquid including at least one of the components added to the treatment liquid of the embodiment of the present invention, the effects of the present invention are noticeably obtained. The treatment liquid of the embodiment of the present invention may be bottled in a container such as a gallon bottle and a coated bottle after the production, transported, and stored.

In order to prevent the modifications in the components in the treatment liquid during the storage, the inside of the container may be purged with inert gas (nitrogen, argon, or the like) with a purity of 99.99995% by volume or more. In particular, a gas having a low moisture content is preferable. In addition, during the transportation or storage, the temperature may be a normal temperature, but may also be controlled to a temperature in the range of −20° C. to 20° C. to prevent deterioration.

[Clean Room]

It is preferable that handlings including production of the treatment liquid of the embodiment of the present invention, opening and/or washing of a housing container, filling of the treatment liquid, and the like, treatment analysis, and measurements are all performed in clean rooms. The clean rooms preferably satisfy International Standards Organization (ISO) 14644-1 clean room standards. It is preferable to satisfy any one of ISO Class 1, ISO Class 2, ISO Class 3, or ISO Class 4, it is more preferable to satisfy either ISO Class 1 or ISO Class 2, and it is still more preferable to satisfy ISO Class 1.

[Filtering]

It is preferable that the treatment liquid of the embodiment of the present invention is filtered in order to remove foreign matters, coarse particles, and the like.

As a filter used for filtering, any filter which has been used in the filtering applications or the like from the related art can be used without particular limitation. Examples of the materials constituting the filter include fluorine-based resins such as polytetrafluoroethylene (PTFE), polyamide-based resins such as nylon, and polyolefin resins (including a high-density polyolefin and an ultrahigh-molecular-weight polyolefin) such as polyethylene and polypropylene (PP). Among these materials, polyamide-based resins, PTFE, and polypropylene (including high-density polypropylene) are preferable, and by using a filter formed with these materials, high-polarity foreign matters which are likely to cause residue defects or particle defects can be more effectively removed.

For the critical surface tension of the filter, the lower limit value is preferably 70 mN/m or more, and the upper limit value is preferably 95 mN/m or less. In particular, the critical surface tension of the filter is preferably from 75 mN/m to 85 mN/m.

In addition, the value of the critical surface tension is a nominal value of a manufacturer. By using a filter having a critical surface tension in the range, high-polarity foreign matters which are likely to cause residue defects or particle defects can be more effectively removed.

The pore diameter of the filter is preferably approximately 0.001 to 1.0 μm, more preferably approximately 0.02 to 0.5 μm, and more preferably approximately 0.01 to 0.1 μm. By adjusting the pore diameter of the filter to be in the range, it is possible to reliably remove fine foreign matters included in the treatment liquid while suppressing clogging in the filtering.

In a case of using filters, different filters may be combined. At that time, the filtering with the first filter may be performed once or twice or more times. In a case where the filtering is performed twice or more times by combining different filters, the respective filters may be of the same kinds or of different kinds from each other, and are preferably of different kinds from each other. Typically, it is preferable that the first filter and the second filter have a difference in at least one of the pore diameter or the constituent materials.

The pore diameter at the second filtering or later is preferably the same as or smaller than the pore diameter at the first filtering. In addition, the first filters with different pore diameters in the above-mentioned range may be combined. Here, with regard to the pore diameters, reference can be made to nominal values of filter manufacturers. A commercially available filter may be selected from various filters provided by Nihon Pall Ltd., Advantech Toyo Roshi Kaisha., Ltd., Nihon Entegris K. K. (formerly Nippon Microlith Co., Ltd.), Kitz Micro Filter Corporation, or the like, for example. Further, a polyamide-made P-nylon Filter (pore diameter of 0.02 μm, critical surface tension of 77 mN/m)”; (manufactured by Nihon Pall Ltd.), a high-density polyethylene-made “PE⋅clean filter (pore diameter of 0.02 μm)”; (manufactured by Nihon Pall Ltd.), and a high-density polyethylene-made “PE⋅clean filter (pore diameter of 0.01 μm)”; (manufactured by Nihon Pall Ltd.) can also be used.

As the second filter, a filter formed of the same materials as those of the first filter can be used. A filter having the same pore diameter as that of the above-mentioned first filter can be used. In a case of using the second filter having a smaller pore diameter than that of the first filter, the ratio of the pore diameter of the second filter to the pore diameter of the first filter (pore diameter of second filter/pore diameter of first filter) is preferably 0.01 to 0.99, more preferably 0.1 to 0.9, and still more preferably 0.3 to 0.9. By adjusting the pore diameter of the second filter to be in the range, fine foreign matters incorporated into the treatment liquid are more reliably removed.

For example, filtering using a first filter may be performed with a mixed liquid including some components of the treatment liquid, the residual components may be mixed therewith to prepare a treatment liquid, and then filtering using a second filter may be performed.

Moreover, the filter used is preferably treated before filtering the treatment liquid. The liquid used in this treatment is not particularly limited, but as long as the liquid is the treatment liquid of the embodiment of the present invention as it is; a dilution of the treatment liquid of the embodiment of the present invention; or a liquid containing the components included in the treatment liquid, desired effects of the present application are noticeably obtained.

In a case of performing filtering, the upper limit value in the temperature during the filtering is preferably room temperature (25° C.) or lower, more preferably 23° C. or lower, and still more preferably 20° C. or lower. Further, the lower limit value in the temperature during the filtering is preferably 0° C. or higher, more preferably 5° C. or higher, and still more preferably 10° C. or higher.

In the filtering, particulate foreign matters or impurities can be removed, but in a case of performing the filtering at the temperature, the amounts of the particulate foreign matters or impurities dissolved in the treatment liquid are reduced, and therefore, the filtering is more efficiently performed.

[Method for Treating Laminate]

The method for treating a laminate of an embodiment of the present invention has a treating step B of subjecting a laminate for a semiconductor device to a treatment, using the treatment liquid, the laminate comprising a substrate, a second layer formed on the substrate, and a first layer formed on the second layer. Further, the method for treating a laminate of the embodiment of the present invention may have a treatment liquid preparing step A of preparing the treatment liquid before the treating step B.

In the following description of a method for treating a laminate, a case where a treatment liquid preparing step A is carried out before the treating step B is shown by way of an example, but is not limited thereto. Further, the method for treating a laminate of the embodiment of the present invention may also be performed using the treatment liquid which has been prepared in advance.

Furthermore, at least one of the removal of the first layer or the removal of dry etching residues is carried out in the treating step B, as described later.

Since the method for treating a laminate of the embodiment of the present invention uses the above-mentioned treatment liquid, the etching property of the first layer (metal hard mask) is excellent and the etching of the second layer (insulating layer) can be suppressed.

<Laminate>

A laminate which is a treatment target comprises a substrate, a second layer formed on the substrate, and a first layer formed on the second layer. The laminate preferably comprises a third layer between the substrate and the second layer.

Specific examples of the laminate include a laminate for a semiconductor device, comprising a substrate, a metal layer (corresponding to the third layer), an interlayer insulating film (corresponding to the second layer), and a metal hard mask (corresponding to the first layer) in this order.

The laminate preferably has holes formed toward the substrate from the surface (apertures) of the metal hard mask so as to expose the surface of the metal layer by further performing a dry etching step or the like.

A method for producing such a laminate having holes is not particularly limited, but common examples thereof include a method in which a laminate before a treatment, having a substrate, a metal layer, an interlayer insulating film, and a metal hard mask in this order, is subjected to a dry etching step using the metal hard mask as a mask, and the interlayer insulating film is etched so as to expose the surface of the metal layer to provide holes passing through the inside of the metal hard mask and the interlayer insulating film.

Furthermore, a method for producing the metal hard mask is not particularly limited, and examples thereof include a method in which a metal hard mask precursor layer including predetermined components is firstly formed on an interlayer insulating film, a resist film having a predetermined pattern is formed thereon, and then the metal hard mask precursor layer is etched using the resist film as a mask to produce a metal hard mask (that is, a film with the metal hard mask precursor layer is patterned).

In addition, the laminate may have layers other than the above-mentioned layer, and examples of such other layers include an etching stop layer and an antireflection layer.

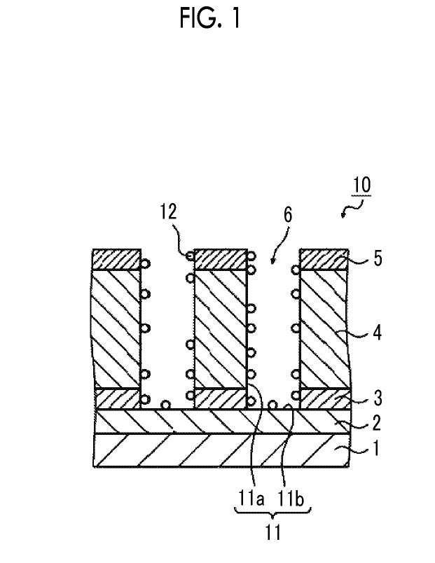

FIG. 1 illustrates a schematic cross-sectional view showing an example of a laminate for a semiconductor device, which is a treatment target.

A laminate 10 shown in FIG. 1 comprises a metal layer 2, an etching stop layer 3, an interlayer insulating film 4, and a metal hard mask 5 in this order on a substrate 1, and has holes 6 formed by a dry etching step, through which a portion of the metal layer 2 is exposed at predetermined positions. That is, the laminate 10 shown in FIG. 1 comprises the substrate 1, the metal layer 2, the etching stop layer 3, the interlayer insulating film 4, and the metal hard mask 5 in this order, in which the holes 6 passing through the surface of the metal hard mask 5 at aperture positions thereof to the surfaces of the metal layer 2 are formed. The inner wall 11 of the holes 6 is formed of a cross-sectional wall 11a formed of the etching stop layer 3, the interlayer insulating film 4, and the metal hard mask 5, and a bottom wall 11b formed of the exposed metal layer 2, and dry etching residues 12 adhere thereto.

The method for treating a laminate of the embodiment of the present invention can also be suitably used in a washing for the purpose of removing the dry etching residues 12 and removing the metal hard mask 5. That is, a performance for removing the dry etching residues 12 and the metal hard mask 5 is excellent, and the etching of the inner wall 11 (for example, the interlayer insulating film 4) of the laminate can be suppressed.

(Metal Hard Mask)

The metal hard mask preferably includes at least one material selected from the group consisting of TiN, TiOx, and ZrOx, where x is a number represented by 1 to 3.

(Interlayer Insulating Film)

The interlayer insulating film (which is referred to as an “insulating film” in some cases in the present specification) is preferably a material having a dielectric constant k of 3.0 or less, and more preferably a material having a dielectric constant k of 2.6 or less.

Specific examples of the material of the interlayer insulating film include SiOx, SiON, and SiOC, where x is a number represented by 1 to 3.

(Etching Stop Layer)

A material for the etching stop layer is not particularly limited. Specific examples of the material for the etching stop layer include an Al-containing compound (for example, AlOx), tetraethoxysilane (TEOS), SiN, SiOC, polycrystalline silicon (poly-Si), and amorphous silicon (a-Si), and the material is preferably an Al-containing compound, and more preferably AlOx, where x is a number represented by 1 to 3.

(Metal Layer)

A wiring material forming the metal layer preferably contains at least one material selected from the group consisting of W, Co, Cu, and Al. Incidentally, the metal may be an alloy with another metal.

(Substrate)

Examples of a “substrate” as mentioned herein include a semiconductor substrate formed of a single layer and a semiconductor substrate formed of multiple layers.

A material constituting the semiconductor substrate formed of a single layer is not particularly limited, and in general, the semiconductor substrate is preferably formed of silicon, silicon germanium, Group III to V compounds such as GaAs, and any combinations thereof.

In a case of a semiconductor substrate formed of multiple layers, its configuration is not particularly limited, and the substrate may have, for example, exposed integrated circuit structures such as interconnect structures (interconnect features) such as a metal wire and a dielectric material on the semiconductor substrate such as silicon as described above. Examples of the metals and the alloys used in the interconnect structures include, but are not limited to, aluminum, aluminum alloyed with copper, copper, titanium, tantalum, cobalt, silicon, titanium nitride, tantalum nitride, and tungsten. Further, there may be layers such as an interlayer dielectric layer, a silicon oxide layer, a silicon nitride layer, a silicon carbide layer, a carbon-doped silicon oxide layer, or the like on the semiconductor substrate.

Hereinafter, the treatment liquid preparing step A and the treating step B will be described, respectively, in detail.

(Treatment Liquid Preparing Step A)

The treatment liquid preparing step A is a step of preparing the treatment liquid. The respective components used in the present step are as described above.

The procedure in the present step is not particularly limited, and examples thereof include a method in which a fluorine-containing compound, a water-soluble aromatic compound, and the other optional components are added to a solvent such as water and/or an organic solvent, and the mixture is stirred and mixed to prepare a treatment liquid.

In addition, as the respective components included in the treatment liquid, those classified into a semiconductor grade or those classified into a high-purity grade equivalent thereto are preferably used. Further, as for components having a large amount of impurities at the time of the raw materials, it is preferable to use the components obtained after performing removal of foreign matters by filtering and reduction in ion components with ion-exchange resins or the like.

(Treating Step B)

In the treating step B, the treatment liquid is brought into contact with the laminate. Thus, at least one of washing for the purpose of removing dry etching residues or removing the metal hard mask (wet etching) is performed.

A method for bringing the treatment liquid into contact with the laminate is not particularly limited, but examples thereof include a method in which a laminate is immersed in a treatment liquid contained in a tank, a method in which a treatment liquid is sprayed onto a laminate, a method in which a treatment liquid is flowed onto a laminate, and any combinations thereof.

A temperature of the treatment liquid is preferably set to 90° C. or lower, more preferably set to 25° C. to 80° C., still more preferably set to 30° C. to 75° C., and particularly preferably set to 40° C. to 65° C.

The treating time can be adjusted depending on a method for contacting the treatment liquid and the temperature of a treatment liquid.

In a case where the treatment is performed in an immersion batch mode (a batch mode in which a plurality of sheets of the laminates are immersed in a treatment tank to perform a treatment), the treating time is, for example, 60 minutes or less, preferably 1 to 60 minutes, more preferably 3 to 20 minutes, and still more preferably 4 to 15 minutes.

In a case where sheet-type treatment is performed, the treating time is, for example, 10 seconds to 5 minutes, preferably 15 seconds to 4 minutes, more preferably 15 seconds to 3 minutes, and still more preferably 20 seconds to 2 minutes.

Furthermore, in order to further enhance the treating capability of the treatment liquid, a mechanical stirring method may be used.

Examples of the mechanical stirring method include a method in which a treatment liquid is circulated on a laminate, a method in which a treatment liquid is flowed through or sprayed on a laminate, and a method in which a treatment liquid is stirred with an ultrasonic or a megasonic.

(Rinsing Step B2)

The method for treating a laminate of the embodiment of the present invention may further have a step (rinsing step B2) of cleaning the laminate by rinsing it with a solvent after the treating step B.

The rinsing step B2 is preferably a step which is performed subsequently after the treating step B, and rinsing is performed with a rinsing solvent (rinsing liquid) over 5 seconds to 5 minutes. The rinsing step B2 may be performed using the above-mentioned mechanical stirring method.

Examples of the rinsing solvent include, but are not limited to, deionized water, methanol, ethanol, isopropyl alcohol, N-methylpyrrolidinone, γ-butyrolactone, dimethyl sulfoxide, ethyl lactate, and propylene glycol monomethyl ether acetate. Alternatively, an aqueous rinsing liquid (diluted aqueous ammonium hydroxide or the like) with a pH>8 may be used.

As the rinsing solvent, an aqueous ammonium hydroxide solution, deionized water, methanol, ethanol, and isopropyl alcohol are preferable, an aqueous ammonium hydroxide solution, deionized water, and isopropyl alcohol are more preferable, and an aqueous ammonium hydroxide solution and deionized water are still more preferable.

As a method for bringing the rinsing solvent into contact with the laminate, the above-mentioned method in which the treatment liquid is brought into contact with a laminate can be applied in the same manner.

The temperature of the rinsing solvent in the rinsing step B2 is preferably 16° C. to 27° C.

The above-mentioned treatment liquid may be used as a rinsing solvent in the rinsing step B2.

(Drying Step B3)

The method for treating a laminate of the embodiment of the present invention may have a drying step B3 in which the laminate is dried after the rinsing step B2.

The drying method is not particularly limited. Examples of the drying method include a spin drying method, a method of flowing a dry gas onto a laminate, a method of heating a substrate by a heating means such as a hot plate or an infrared lamp, a Marangoni drying method, a Rotagoni drying method, an isopropyl alcohol (IPA) drying method, or any combinations thereof.

The drying time depends on a specific method used, but in general, is preferably 30 seconds to several minutes.

(Coarse Particle Removing Step H)

The method for treating a laminate of the embodiment of the present invention preferably has a coarse particle removing step H in which the coarse particles in the treatment liquid are removed, before carrying out the treating step B.

By reducing or removing the coarse particles in the treatment liquid, it is possible to reduce the amount of the coarse particles remaining on the laminate obtained after performing the treating step B. As a result, it is possible to suppress pattern damages caused by the coarse particles on the laminate, and an influence on a yield loss of a device and a decrease in reliability can also be suppressed.

Specific examples of a method for removing the coarse particle include a method in which the treatment liquid obtained after performing the treatment liquid preparing step A is purified by filtering, using a particle removing film having a predetermined particle removal diameter.

In addition, the definition of the coarse particles is as described above.

(Charge Eliminating Steps I and J)

It is preferable that the method for treating a laminate of the embodiment of the present invention uses water during the preparation of the treatment liquid in the treatment liquid preparing step A, and includes a charge eliminating step I in which the water is subjected to charge elimination before the treatment liquid preparing step A and/or a charge eliminating step J in which the treatment liquid is subjected to charge elimination before performing the treating step B after the treatment liquid preparing step A.

It is preferable that a material for a liquid contact portion for supplying the treatment liquid to the laminate is a resin having no metal elution to the treatment liquid.

As a result, it is preferable that in the method for treating a laminate of the embodiment of the present invention, at least one step of the above-mentioned charge eliminating step I or charge eliminating step J is carried out to reduce the charging potential of the treatment liquid. Further, by performing charge elimination, adherence of foreign matters (coarse particles or the like) onto a substrate or damages (corrosion) on the laminate can be further suppressed.

Specific examples of the charge eliminating method include a method in which water and/or the treatment liquid is brought into contact with an electrically conductive material.

The contact time during which water and/or the treatment liquid is brought into contact with the electrically conductive material is preferably 0.001 to 1 second, and more preferably 0.01 to 0.1 seconds.

Specific examples of the resin include high-density polyethylene (HDPE), high-density polypropylene (PP), 6,6-nylon, tetrafluoroethylene (PTFE), a tetrafluoroethylene/perfluoroalkylvinyl ether copolymer (PFA), polychlorotrifluoroethylene (PCTFE), an ethylene/chlorotrifluoroethylene copolymer (ECTFE), an ethylene/ethylene tetrafluoride copolymer (ETFE), and an ethylene tetrafluoride/propylene hexafluoride copolymer (FEP).

Examples of the electrically conductive material include stainless steel, gold, platinum, diamond, and glassy carbon.

In the method for treating a laminate using the treatment liquid of the embodiment of the present invention, it is possible to reuse a drainage of the treatment liquid used in the treating step B, and use it to wash another laminate.

The method for treating a laminate of the embodiment of the present invention preferably includes the following steps in a case of an aspect where the drainage of the treatment liquid is reused:

the treating step B;

a drainage recovering step C in which a drainage of the treatment liquid used in the treating step B is recovered;

a treating step D in which a newly prepared laminate is treated using the recovered drainage of the treatment liquid;

a drainage recovering step E in which a drainage of the treatment liquid used in the treating step D is recovered; and

a step in which the treating step D and the drainage recovering step E are repeated.

In the aspect of reusing the drainage, the treating step B has the same definition as the treating step B described in the above-mentioned aspect, and a preferred aspect thereof is also the same. Also, in the aspect of reusing the drainage, the method preferably has the coarse particle removing step H, and the charge eliminating steps I and J described. In addition, the method may have the treatment liquid preparing step A described in the above-mentioned aspect before the treating step B.

The treating step D has the same definition as the treating step B in the above-mentioned aspect, and a preferred aspect thereof is also the same.

A drainage recovering means in the drainage recovering steps C and E is not particularly limited. The recovered drainage is preferably stored in the above-mentioned resin-made container in the charge eliminating step J, and the same charge eliminating step as the charge eliminating step J may be performed at this time. In addition, a step in which the recovered drainage is subjected to filtering or the like to remove impurities may be provided.

### EXAMPLES

Hereinbelow, the present invention will be described in detail with reference to Examples, but the present invention is not limited thereto. Further, “%” is based on mass unless otherwise specified.

### Examples 1-1 to 1-77 and Comparative Examples 1-1 and 1-2

<Preparation of Treatment Liquid>

The respective components shown in Table 1 were mixed and stirred such that the total amount of the respective components became 100% by mass, thereby obtaining each of the treatment liquids of Examples and Comparative Examples.

The components used for the preparation of each of the treatment liquids of Examples and Comparative Example are as follows.

<Fluorine-Containing Compound>

HF: Hydrogen fluoride (manufactured by Kanto Chemical Co., Inc.)

<Water-Soluble Aromatic Compound>

Phthalic acid: pKa of 2.98 (manufactured by Wako Pure Chemical Industries, Ltd.), 74 g/L (25° C.)

Phenylphosphonic acid: pKa of 1.86 (manufactured by Tokyo Kasei Kogyo Co., Ltd.), 400 g/L (25° C.) p-Toluenesulfonic acid: pKa of −2.15 (manufactured by Tokyo Kasei Kogyo Co., Ltd.), 670 g/L (25° C.)

Anthranilic acid: pKa of 2.00 (manufactured by Tokyo Kasei Kogyo Co., Ltd.), 4.5 g/L (25° C.)

Salicylic acid: pKa of 2.78 (manufactured by Wako Pure Chemical Industries, Ltd.), 3.3 g/L (25° C.)

Catechol: pKa of more than 14 (manufactured by Wako Pure Chemical Industries, Ltd.), 312 g/L (25° C.) p-Xylylenediamine: pKa of more than 14 (manufactured by Tokyo Kasei Kogyo Co., Ltd.), 100 g/L or more (25° C.)

<Surfactant>

Phosten HLP: Trade name “NIKKOL PHOSTEN HLP” (manufactured by Nikko Chemicals Co., Ltd.), anionic surfactant

PELEX SSL: Anionic surfactant (trade name, manufactured by Kao Corporation)

PELEX NBL: Anionic surfactant (trade name, manufactured by Kao Corporation)

LATEMUL ASK: Anionic surfactant (trade name, manufactured by Kao Corporation)

Dodecanoic acid: Anionic surfactant (manufactured by Wako Pure Chemical Industries, Ltd.)

Dodecanedioic acid: Anionic surfactant (manufactured by Wako Pure Chemical Industries, Ltd.)

<Corrosion Inhibitor>

5-MBTA: 5-Methyl-1H-benzotriazole (manufactured by Wako Pure Chemical Industries, Ltd.)

BTA: Benzotriazole (manufactured by Wako Pure Chemical Industries, Ltd.)

IRGAMET 42: 2,2′-{[(4-Methyl-1H-benzotriazole-1-yl)methyl]imino}bisethanol (manufactured by BASF)

IRGAMET 39: N,N-Bis(2-ethylhexyl)-(4 or 5)-methyl-1H-benzotriazole-1-methylamine (manufactured by BASF)

Citric acid: (manufactured by Wako Pure Chemical Industries, Ltd.)

<Boron-Containing Compound>

Boric acid: (manufactured by Wako Pure Chemical Industries, Ltd.) Monophenyl borate: (manufactured by Tokyo Kasei Kogyo Co., Ltd.)

<Polymer Compound>

PAA (MW of 5,000): Polyacrylic acid, weight-average molecular weight (Mw) of 5,000, (manufactured by Wako Pure Chemical Industries, Ltd.), anionic polymer

PAA (MW of 500): Polyacrylic acid, weight-average molecular weight (Mw) of 500, (manufactured by Wako Pure Chemical Industries, Ltd.), anionic polymer

PAA (MW of 25,000): Polyacrylic acid, weight-average molecular weight (Mw) of 25,000, (manufactured by Wako Pure Chemical Industries, Ltd.), anionic polymer

PAA (MW of 150,000): Polyacrylic acid, weight-average molecular weight (Mw) of 150,000, (manufactured by Wako Pure Chemical Industries, Ltd.), anionic polymer

Polystyrenesulfonic acid (MW of 3,000): Weight-average molecular weight (Mw) of 3,000, (manufactured by Tokyo Kasei Kogyo Co., Ltd.), anionic polymer

Polyphosphoric acid (MW of 5,000): Weight-average molecular weight (Mw) of 5,000, (manufactured by Wako Pure Chemical Industries, Ltd.), anionic polymer

Polyethylenimine (MW of 5,000): Weight-average molecular weight (Mw) of 5,000, (manufactured by BASF), cationic polymer

Polyallylamine (MW of 5,000): Weight-average molecular weight (Mw) of 5,000, (manufactured by BASF), cationic polymer

<Metal Ion>

As the metal ion, a metal ion in the form of a metal chloride was added to the treatment liquid.

SrCl₂ (described as “SrCl2” in the tables): (manufactured by Wako Pure Chemical Industries, Ltd.)

BaCl₂ (described as “BaCl2” in the tables): (manufactured by Wako Pure Chemical Industries, Ltd.)

CaCl₂ (described as “CaCl2” in the tables): (manufactured by Wako Pure Chemical Industries, Ltd.)

AlCl₃ (described as “AlCl3” in the tables): (manufactured by Wako Pure Chemical Industries, Ltd.)

KCl: (manufactured by Wako Pure Chemical Industries, Ltd.) LaCl₃ (described as “LaCl3” in the tables): (manufactured by Wako Pure Chemical Industries, Ltd.)

TiCl₃ (described as “TiCl3” in the tables): (manufactured by Wako Pure Chemical Industries, Ltd.)

CuCl₂ (described as “CuCl2” in the tables): (manufactured by Wako Pure Chemical Industries, Ltd.)

ZnCl₂ (described as “ZnCl2” in the tables): (manufactured by Wako Pure Chemical Industries, Ltd.)

<Organic Solvent>

EGBE: Ethylene glycol mono-n-butyl ether (manufactured by Wako Pure Chemical Industries, Ltd.)

HG: Hexylene glycol (manufactured by Wako Pure Chemical Industries, Ltd.)

DEGBE: Diethylene glycol monobutyl ether (manufactured by Wako Pure Chemical Industries, Ltd.)

The organic solvent was purified by repeatedly performing distillation in a distillation column formed with glass, and then by repeatedly performing ion exchange and filtering through a filter.

<Water>

Water was purified by the method described in JP2007-254168A and used for the preparation of a treatment liquid.

<pH Adjuster>

MSA: Methanesulfonic acid (manufactured by Wako Pure Chemical Industries, Ltd.)

DBU: Diazabicycloundecene (manufactured by Wako Pure Chemical Industries, Ltd.)

In addition, the pH adjuster was added in an appropriate amount (1% by mass or less with respect to the total mass of the treatment liquid) such that the pH of the treatment liquid became the values in the tables.

<Others>

(Oxidizing Agent)

Nitric Acid

[Physical Properties of Treatment Liquid]

<pH>

The pH of each of the treatment liquids of Examples and Comparative Examples at 23° C. was measured using a pH meter (trade name “pH Meter F-51” manufactured by HORIBA Ltd.).

[Evaluation Test]

<Etching Performance>

A model film (each of the films of TiN, ZrOx, Al, AlOx, W, Co, Cu, SiO₂, SiON, and SiOC) formed of the respective materials described in Table 1 was prepared, and an etching property thereof was evaluated, based on the etching rate. The film thickness of the model film is 1,000 Å. Further, x is a number represented by 1 to 3.

Using each of the treatment liquids of Examples and Comparative Examples, each of the model films was subjected to an etching treatment. Specifically, each of the model films was immersed in each of the treatment liquids of Examples and Comparative Examples for 10 minutes, and the etching rate (A/min) was calculated, based on a difference in the film thickness of the model film between before and after the immersion in the treatment liquid.

Furthermore, the film thickness of the model film before and after the treatment was measured using ellipsometry (spectroscopic ellipsometer, trade name “Vase”, manufactured by J. A. Woollam Co.) under the conditions of a measuring range of 250 to 1,000 nm and measuring angles of 70 degrees and 75 degrees.

[Evaluation Results]

The above evaluation results are shown in Table 1. Further, “>0.5” in the table is a value of greater than 0.5. In addition, “>0.1” is a value of greater than 0.1.

TABLE 1

| | | Water-soluble | | | | |
|---|---|---|---|---|---|---|
| | Fluorine-containing | aromatic | | Corrosion | | Boron-containing |
| | compound | compound | Surfactant | inhibitor | | compound |
| Example 1-1 | HF | Phthalic acid | | | | |
| | 1.2% | 8.0% | | | | |
| Example 1-2 | HF | Phthalic acid | | | | |
| | 1.2% | 1.0% | | | | |
| Example 1-3 | HF | Phthalic acid | | | | |
| | 1.2% | 4.0% | | | | |
| Example 1-4 | HF | Phenylphosphonic | | Citric | | |
| | 1.2% | acid | | acid | | |
| | | 1.0% | | 2.0% | | |
| Example 1-5 | HF | p-Toluenesulfonic | | Citric | | |
| | 1.2% | acid | | acid | | |
| | | 1.0% | | 2.0% | | |
| Example 1-6 | HF | p-Toluenesulfonic | | Citric | | |
| | 1.2% | acid | | acid | | |
| | | 0.3% | | 2.0% | | |
| Example 1-7 | HF | Anthranilic acid | | Citric | | |
| | 1.2% | 1.0% | | acid | | |
| | | | | 2.0% | | |
| Example 1-8 | HF | Anthranilic acid | | Citric | | |
| | 1.2% | 8.0% | | acid | | |
| | | | | 2.0% | | |
| Example 1-9 | HF | Salicylic acid | | Citric | | |
| | 1.2% | 1.0% | | acid | | |
| | | | | 2.0% | | |
| Example 1-10 | HF | Catechol | | Citric | | |
| | 1.2% | 1.0% | | acid | | |
| | | | | 2.0% | | |
| Example 1-11 | HF | Xylylenediamine | | Citric | | |
| | 1.2% | 1.0% | | acid | | |
| | | | | 2.0% | | |
| Example 1-12 | HF | Phthalic acid | | | | |
| | 1.2% | 8.0% | | | | |
| Example 1-13 | HF | Phthalic acid | | | | |
| | 1.2% | 8.0% | | | | |
| Example 1-14 | HF | Phthalic acid | | | | |
| | 1.2% | 8.0% | | | | |
| Example 1-15 | HF | Phthalic acid | | | | |
| | 0.6% | 8.0% | | | | |
| Example 1-16 | HF | p-Toluenesulfonic | | | | |
| | 1.8% | acid | | | | |
| | | 0.3% | | | | |
| Example 1-17 | HF | p-Toluenesulfonic | | | | |
| | 2.4% | acid | | | | |
| | | 0.3% | | | | |
| Comparative | | Phthalic acid | | | | |
| Example 1-1 | | 8.0% | | | | |
| Comparative | HF | | | | | |
| Example 1-2 | 1.2% | | | | | |
| Example 1-18 | HF | Phthalic acid | Phosten HLP | | | |
| | 1.2% | 8.0% | 0.03% | | | |
| Example 1-19 | HF | Phthalic acid | Phosten HLP | 5-MBTA | | |
| | 1.2% | 8.0% | 0.03% | 0.25% | | |
| Example 1-20 | HF | Phthalic acid | Phosten HLP | 5-MBTA | | Boric acid |
| | 1.2% | 8.0% | 0.03% | 0.25% | | 0.10% |
| Example 1-21 | HF | Phthalic acid | Phosten HLP | 5-MBTA | | Boric acid |
| | 1.2% | 8.0% | 0.03% | 0.25% | | 0.10% |
| Example 1-22 | HF | Phthalic acid | Phosten HLP | 5-MBTA | | Boric acid |
| | 1.2% | 8.0% | 0.03% | 0.25% | | 0.10% |
| Example 1-23 | HF | Phthalic acid | Phosten HLP | 5-MBTA | | Boric acid |
| | 1.2% | 8.0% | 0.03% | 0.25% | | 0.10% |
| Example 1-24 | HF | Phthalic acid | Phosten HLP | 5-MBTA | | Boric acid |
| | 1.2% | 8.0% | 0.03% | 0.25% | | 0.10% |
| Example 1-25 | HF | Phthalic acid | Phosten HLP | 5-MBTA | | Boric acid |
| | 1.2% | 8.0% | 0.03% | 0.25% | | 0.10% |
| Example 1-26 | HF | Phthalic acid | Phosten HLP | 5-MBTA | | Boric acid |
| | 0.6% | 8.0% | 0.03% | 0.25% | | 0.10% |
| Example 1-27 | HF | Phthalic acid | Phosten HLP | 5-MBTA | | Boric acid |
| | 1.8% | 8.0% | 0.03% | 0.25% | | 0.10% |
| Example 1-28 | HF | Phthalic acid | Phosten HLP | 5-MBTA | | Boric acid |
| | 1.2% | 8.0% | 0.03% | 0.25% | | 0.10% |
| Example 1-29 | HF | Phthalic acid | Phosten HLP | 5-MBTA | | Boric acid |
| | 1.2% | 8.0% | 0.03% | 0.25% | | 0.10% |
| Example 1-30 | HF | Phthalic acid | Phosten HLP | 5-MBTA | | Boric acid |
| | 1.2% | 8.0% | 0.03% | 0.25% | | 0.10% |
| Example 1-31 | HF | Phthalic acid | Phosten HLP | 5-MBTA | | Boric acid |
| | 1.2% | 8.0% | 0.03% | 0.25% | | 0.10% |
| Example 1-32 | HF | Phthalic acid | Phosten HLP | 5-MBTA | | Boric acid |
| | 1.2% | 8.0% | 0.03% | 0.25% | | 0.10% |
| Example 1-33 | HF | Phthalic acid | Phosten HLP | 5-MBTA | | Boric acid |
| | 1.2% | 8.0% | 0.03% | 0.25% | | 0.10% |
| Example 1-34 | HF | Phthalic acid | Phosten HLP | 5-MBTA | | Boric acid |
| | 1.2% | 8.0% | 0.03% | 0.25% | | 0.10% |
| Example 1-35 | HF | Phthalic acid | Phosten HLP | 5-MBTA | | Boric acid |
| | 1.2% | 8.0% | 0.03% | 0.25% | | 0.10% |
| Example 1-36 | HF | Phthalic acid | Phosten HLP | 5-MBTA | | Boric acid |
| | 1.2% | 8.0% | 0.03% | 0.25% | | 0.10% |
| Example 1-37 | HF | Phthalic acid | Phosten HLP | 5-MBTA | | Boric acid |
| | 1.2% | 8.0% | 0.03% | 0.25% | | 0.10% |
| Example 1-38 | HF | Phthalic acid | Phosten HLP | 5-MBTA | | Boric acid |
| | 1.2% | 8.0% | 0.03% | 0.25% | | 0.10% |
| Example 1-39 | HF | Phthalic acid | Phosten HLP | 5-MBTA | | Boric acid |
| | 1.2% | 8.0% | 0.03% | 0.25% | | 0.10% |
| Example 1-40 | HF | Phthalic acid | Phosten HLP | 5-MBTA | | Boric acid |
| | 1.2% | 8.0% | 0.03% | 0.25% | | 0.10% |
| Example 1-41 | HF | Phthalic acid | Phosten HLP | 5-MBTA | | Boric acid |
| | 1.2% | 8.0% | 0.03% | 0.25% | | 0.10% |
| Example 1-42 | HF | Phthalic acid | Phosten HLP | 5-MBTA | | Boric acid |
| | 1.2% | 8.0% | 0.03% | 0.25% | | 0.10% |
| Example 1-43 | HF | Phthalic acid | Phosten HLP | 5-MBTA | | Boric acid |
| | 1.2% | 8.0% | 0.03% | 0.25% | | 0.10% |
| Example 1-44 | HF | Phthalic acid | Phosten HLP | 5-MBTA | | Boric acid |
| | 1.2% | 8.0% | 0.03% | 0.25% | | 0.10% |
| Example 1-45 | HF | Phthalic acid | Phosten HLP | 5-MBTA | | Boric acid |
| | 1.2% | 8.0% | 0.03% | 0.25% | | 0.10% |
| Example 1-46 | HF | Phthalic acid | Phosten HLP | 5-MBTA | | Boric acid |
| | 1.2% | 8.0% | 0.03% | 0.25% | | 0.10% |
| Example | HF | Phthalic acid | Phosten HLP | 5-MBTA | | Boric acid |
| 1-47 | 1.2% | 1.0% | 0.03% | 0.25% | | 0.10% |
| Example | HF | Phthalic acid | Phosten HLP | 5-MBTA | | Boric acid |
| 1-48 | 1.2% | 4.0% | 0.03% | 0.25% | | 0.10% |
| Example | HF | Phenylphosphonic acid | Phosten HLP | 5-MBTA | Citric acid | Boric acid |
| 1-49 | 1.2% | 1.0% | 0.03% | 0.25% | 2.0% | 0.10% |
| Example | HF | p-Toluenesulfonic acid | Phosten HLP | 5-MBTA | Citric acid | Boric acid |
| 1-50 | 1.2% | 1.0% | 0.03% | 0.25% | 2.0% | 0.10% |
| Example | HF | p-Toluenesulfonic acid | Phosten HLP | 5-MBTA | Citric acid | Boric acid |
| 1-51 | 1.2% | 0.3% | 0.03% | 0.25% | 2.0% | 0.10% |
| Example | HF | Anthranilic acid | Phosten HLP | 5-MBTA | Citric acid | Boric acid |
| 1-52 | 1.2% | 1.0% | 0.03% | 0.25% | 2.0% | 0.10% |
| Example | HF | Anthranilic acid | Phosten HLP | 5-MBTA | Citric acid | Boric acid |
| 1-53 | 1.2% | 8.0% | 0.03% | 0.25% | 2.0% | 0.10% |
| Example | HF | Salicylic acid | Phosten HLP | 5-MBTA | Citric acid | Boric acid |
| 1-54 | 1.2% | 1.0% | 0.03% | 0.25% | 2.0% | 0.10% |
| Example | HF | Catechol | Phosten HLP | 5-MBTA | Citric acid | Boric acid |
| 1-55 | 1.2% | 1.0% | 0.03% | 0.25% | 2.0% | 0.10% |
| Example | HF | p-Xylylenediamine | Phosten HLP | 5-MBTA | Citric acid | Boric acid |
| 1-56 | 1.2% | 1.0% | 0.03% | 0.25% | 2.0% | 0.10% |
| Example | HF | Phthalic acid | Phosten HLP | 5-MBTA | | Boric acid |
| 1-57 | 1.2% | 8.0% | 0.03% | 0.05% | | 0.10% |
| Example | HF | Phthalic acid | Phosten HLP | 5-MBTA | | Boric acid |
| 1-58 | 1.2% | 8.0% | 0.03% | 0.50% | | 0.10% |
| Example | HF | Phthalic acid | Phosten HLP | BTA | | Boric acid |
| 1-59 | 1.2% | 8.0% | 0.03% | 0.25% | | 0.10% |
| Example | HF | Phthalic acid | Phosten HLP | Irgamet42 | | Boric acid |
| 1-60 | 1.2% | 8.0% | 0.03% | 0.25% | | 0.10% |
| Example | HF | Phthalic acid | Phosten HLP | Irgamet39 | | Boric acid |
| 1-61 | 1.2% | 8.0% | 0.03% | 0.25% | | 0.10% |
| Example | HF | Phthalic acid | Phosten HLP | 5-MBTA | | Boric acid |
| 1-62 | 1.2% | 8.0% | 0.003% | 0.25% | | 0.10% |
| Example | HF | Phthalic acid | Phosten HLP | 5-MBTA | | Boric acid |
| 1-63 | 1.2% | 8.0% | 0.3% | 0.25% | | 0.10% |
| Example | HF | Phthalic acid | PELEX SSL | 5-MBTA | | Boric acid |
| 1-64 | 1.2% | 8.0% | 0.08% | 0.25% | | 0.10% |
| Example | HF | Phthalic acid | PELEX NBL | 5-MBTA | | Boric acid |
| 1-65 | 1.2% | 8.0% | 0.11% | 0.25% | | 0.10% |
| Example | HF | Phthalic acid | LATEMUL ASK | 5-MBTA | | Boric acid |
| 1-66 | 1.2% | 8.0% | 0.14% | 0.25% | | 0.10% |
| Example | HF | Phthalic acid | Phosten HLP | 5-MBTA | | Boric acid |
| 1-67 | 1.2% | 8.0% | 0.03% | 0.25% | | 0.10% |
| Example | HF | Phthalic acid | Dodecanoic acid | 5-MBTA | | Boric acid |
| 1-68 | 1.2% | 8.0% | 0.03% | 0.25% | | 0.10% |
| Example | HF | Phthalic acid | Dodecanedioic acid | 5-MBTA | | Boric acid |
| 1-69 | 1.2% | 8.0% | 0.03% | 0.25% | | 0.10% |
| Example | HF | Phthalic acid | Phosten HLP | 5-MBTA | | Boric acid |
| 1-70 | 1.2% | 8.0% | 0.03% | 0.25% | | 0.01% |
| Example | HF | Phthalic acid | | 5-MBTA | | Boric acid |
| 1-71 | 1.2% | 8.0% | | 0.25% | | 1.0% |
| Example | HF | Phthalic acid | Phosten HLP | 5-MBTA | | Monophenyl borate |
| 1-72 | 1.2% | 8.0% | 0.03% | 0.25% | | 0.10% |
| Example | HF | Phthalic acid | | 5-MBTA | | Boric acid |
| 1-73 | 1.2% | 8.0% | | 0.25% | | 0.10% |
| Example | HF | Phthalic acid | | 5-MBTA | | Boric acid |
| 1-74 | 1.2% | 8.0% | | 0.25% | | 0.10% |
| Example | HF | Phthalic acid | | 5-MBTA | | Boric acid |
| 1-75 | 1.2% | 8.0% | | 0.25% | | 0.10% |
| Example | HF | Phthalic acid | | 5-MBTA | | Boric acid |
| 1-76 | 1.2% | 8.0% | | 0.25% | | 0.10% |
| Example | HF | Phthalic acid | Phosten HLP | 5-MBTA | | Boric acid |
| 1-77 | 1.2% | 8.0% | 0.03% | 0.25% | | 0.10% |

| | | | | | | | | | Evaluation | |
|---|---|---|---|---|---|---|---|---|---|---|
| | | | | | | | | | results | |
| | | | | | | | | | Etching | |
| | | | | | | | | Content | performance | |
| | Polymer | Metal | Organic | | | | | ratio | (Å/min) | |
| | compound | ion | solvent | Others | Water | pH adjuster | pH | (M1/M2) | TiN | ZrOx |
| Example 1-1 | | | | | Balance | MSA/DBU | 4.5 | 0.15 | 2.5 | 1.5 |
| Example 1-2 | | | | | Balance | MSA/DBU | 4.5 | 1.2 | 2.4 | 2.0 |
| Example 1-3 | | | | | Balance | MSA/DBU | 4.5 | 0.3 | 2.2 | 1.8 |
| Example 1-4 | | | | | Balance | MSA/DBU | 4.5 | 1.2 | 2.6 | 2.4 |
| Example 1-5 | | | | | Balance | MSA/DBU | 4.5 | 1.2 | 2.6 | 2.2 |
| Example 1-6 | | | | | Balance | MSA/DBU | 4.5 | 4 | 2.6 | 2.2 |
| Example 1-7 | | | | | Balance | MSA/DBU | 4.5 | 1.2 | 2.5 | 2.1 |
| Example 1-8 | | | | | Balance | MSA/DBU | 4.5 | 0.15 | 2.6 | 2.2 |
| Example 1-9 | | | | | Balance | MSA/DBU | 4.5 | 1.2 | 2.6 | 2.2 |
| Example 1-10 | | | | | Balance | MSA/DBU | 4.5 | 1.2 | 2.6 | 2.2 |
| Example 1-11 | | | | | Balance | MSA/DBU | 4.5 | 1.2 | 2.6 | 2.2 |
| Example 1-12 | | | | | Balance | MSA/DBU | 3.5 | 0.15 | 2.5 | 1.9 |
| Example 1-13 | | | | | Balance | MSA/DBU | 4 | 0.15 | 2.2 | 1.6 |
| Example 1-14 | | | | | Balance | MSA/DBU | 5 | 0.15 | 1.7 | 1.2 |
| Example 1-15 | | | | | Balance | MSA/DBU | 4.5 | 0.075 | 1.0 | 0.8 |
| Example 1-16 | | | | | Balance | MSA/DBU | 4.5 | 6 | 3.5 | 2.6 |
| Example 1-17 | | | | | Balance | MSA/DBU | 4.5 | 8 | 4.5 | 2.8 |
| Comparative | | | | | Balance | MSA/DBU | 4.5 | — | >0.5 | >0.5 |
| Example 1-1 | | | | | | | | | | |
| Comparative | | | | | Balance | MSA/DBU | 4.5 | — | >0.1 | 1.6 |
| Example 1-2 | | | | | | | | | | |
| Example 1-18 | | | | | Balance | MSA/DBU | 4.5 | 0.15 | 1.9 | 1.5 |
| Example 1-19 | | | | | Balance | MSA/DBU | 4.5 | 0.15 | 1.8 | 1.4 |
| Example 1-20 | | | | | Balance | MSA/DBU | 4.5 | 0.15 | 1.9 | 1.5 |
| Example 1-21 | PAA (MW of 5,000) | | | | Balance | MSA/DBU | 4.5 | 0.15 | 2.0 | 1.4 |
| | 0.5% | | | | | | | | | |
| Example 1-22 | PAA (MW of 5,000) | SrCl2 | | | Balance | MSA/DBU | 4.5 | 0.15 | 2.0 | 1.4 |
| | 0.5% | 0.1% | | | | | | | | |
| Example 1-23 | PAA (MW of 5,000) | SrCl2 | | | Balance | MSA/DBU | 3.5 | 0.15 | 2.5 | 1.9 |
| | 0.5% | 0.1% | | | | | | | | |
| Example 1-24 | PAA (MW of 5,000) | SrCl2 | | | Balance | MSA/DBU | 4 | 0.15 | 2.2 | 1.6 |
| | 0.5% | 0.1% | | | | | | | | |
| Example 1-25 | PAA (MW of 5,000) | SrCl2 | | | Balance | MSA/DBU | 5 | 0.15 | 1.7 | 1.2 |
| | 0.5% | 0.1% | | | | | | | | |
| Example 1-26 | PAA (MW of 5,000) | SrCl2 | | | Balance | MSA/DBU | 4.5 | 0.075 | 1.1 | 0.8 |
| | 0.5% | 0.1% | | | | | | | | |
| Example 1-27 | PAA (MW of 5,000) | SrCl2 | | | Balance | MSA/DBU | 4.5 | 0.225 | 4.0 | 3.2 |
| | 0.5% | 0.1% | | | | | | | | |
| Example 1-28 | PAA (MW of 5,000) | SrCl2 | | | Balance | MSA/DBU | 4.5 | 0.15 | 2.0 | 1.4 |
| | 0.5% | 0.01% | | | | | | | | |
| Example 1-29 | PAA (MW of 5,000) | SrCl2 | | | Balance | MSA/DBU | 4.5 | 0.15 | 2.0 | 1.4 |
| | 0.5% | 0.001% | | | | | | | | |
| Example 1-30 | PAA (MW of 5,000) | BaCl2 | | | Balance | MSA/DBU | 4.5 | 0.15 | 2.0 | 1.4 |
| | 0.5% | 0.1% | | | | | | | | |
| Example 1-31 | PAA (MW of 5,000) | CaCl2 | | | Balance | MSA/DBU | 4.5 | 0.15 | 2.0 | 1.4 |
| | 0.5% | 0.1% | | | | | | | | |
| Example 1-32 | PAA (MW of 5,000) | AlCl3 | | | Balance | MSA/DBU | 4.5 | 0.15 | 2.0 | 1.4 |
| | 0.5% | 0.1% | | | | | | | | |
| Example 1-33 | PAA (MW of 5,000) | KCl | | | Balance | MSA/DBU | 4.5 | 0.15 | 2.0 | 1.4 |
| | 0.5% | 0.1% | | | | | | | | |
| Example 1-34 | PAA (MW of 5,000) | LaCl3 | | | Balance | MSA/DBU | 4.5 | 0.15 | 2.0 | 1.4 |
| | 0.5% | 0.1% | | | | | | | | |
| Example 1-35 | PAA (MW of 5,000) | TiCl3 | | | Balance | MSA/DBU | 4.5 | 0.15 | 2.0 | 1.4 |
| | 0.5% | 0.1% | | | | | | | | |
| Example 1-36 | PAA (MW of 5,000) | CuCl2 | | | Balance | MSA/DBU | 4.5 | 0.15 | 2.0 | 1.4 |
| | 0.5% | 0.1% | | | | | | | | |
| Example 1-37 | PAA (MW of 5,000) | ZnCl2 | | | Balance | MSA/DBU | 4.5 | 0.15 | 2.0 | 1.4 |
| | 0.5% | 0.1% | | | | | | | | |
| Example 1-38 | PAA (MW of 5,000) | SrCl2 | | | Balance | MSA/DBU | 4.5 | 0.15 | 2.0 | 1.4 |
| | 0.05% | 0.1% | | | | | | | | |
| Example 1-39 | PAA (MW of 5,000) | SrCl2 | | | Balance | MSA/DBU | 4.5 | 0.15 | 2.0 | 1.4 |
| | 2.0% | 0.1% | | | | | | | | |
| Example 1-40 | PAA (MW of 500) | SrCl2 | | | Balance | MSA/DBU | 4.5 | 0.15 | 2.0 | 1.4 |
| | 0.5% | 0.1% | | | | | | | | |
| Example 1-41 | PAA (MW of 25,000) | SrCl2 | | | Balance | MSA/DBU | 4.5 | 0.15 | 2.0 | 1.4 |
| | 0.5% | 0.1% | | | | | | | | |
| Example 1-42 | PAA (MW of 150,000) | SrCl2 | | | Balance | MSA/DBU | 4.5 | 0.15 | 2.0 | 1.4 |
| | 0.5% | 0.1% | | | | | | | | |
| Example 1-43 | Polystyrenesulfonic acid | SrCl2 | | | Balance | MSA/DBU | 4.5 | 0.15 | 2.0 | 1.4 |
| | (MW of 3,000) | 0.1% | | | | | | | | |
| | 0.5% | | | | | | | | | |
| Example 1-44 | Polyphosphoric acid | SrCl2 | | | Balance | MSA/DBU | 4.5 | 0.15 | 2.0 | 1.4 |
| | (MW of 5,000) | 0.1% | | | | | | | | |
| | 0.5% | | | | | | | | | |
| Example 1-45 | Polyethylenimine (MW | SrCl2 | | | Balance | MSA/DBU | 4.5 | 0.15 | 2.0 | 1.4 |
| | of 5,000) | 0.1% | | | | | | | | |
| | 0.5% | | | | | | | | | |
| Example 1-46 | Polyallylamine (MW of | SrCl2 | | | Balance | MSA/DBU | 4.5 | 0.15 | 2.0 | 1.4 |
| | 5,000) | 0.1% | | | | | | | | |
| | 0.5% | | | | | | | | | |
| Example | PAA (MW of 5,000) | SrCl2 | | | Balance | MSA/DBU | 4.5 | 1.2 | 2.4 | 2.0 |
| 1-47 | 0.5% | 0.1% | | | | | | | | |
| Example | PAA (MW of 5,000) | SrCl2 | | | Balance | MSA/DBU | 4.5 | 0.3 | 2.2 | 1.8 |
| 1-48 | 0.5% | 0.1% | | | | | | | | |
| Example | PAA (MW of 5,000) | SrCl2 | | | Balance | MSA/DBU | 4.5 | 1.2 | 2.6 | 2.4 |
| 1-49 | 0.5% | 0.1% | | | | | | | | |
| Example | PAA (MW of 5,000) | SrCl2 | | | Balance | MSA/DBU | 4.5 | 1.2 | 2.6 | 2.2 |
| 1-50 | 0.5% | 0.1% | | | | | | | | |
| Example | PAA (MW of 5,000) | SrCl2 | | | Balance | MSA/DBU | 4.5 | 4 | 2.5 | 2.1 |
| 1-51 | 0.5% | 0.1% | | | | | | | | |
| Example | PAA (MW of 5,000) | SrCl2 | | | Balance | MSA/DBU | 4.5 | 1.2 | 2.5 | 2.1 |
| 1-52 | 0.5% | 0.1% | | | | | | | | |
| Example | PAA (MW of 5,000) | SrCl2 | | | Balance | MSA/DBU | 4.5 | 0.15 | 2.5 | 2.1 |
| 1-53 | 0.5% | 0.1% | | | | | | | | |
| Example | PAA (MW of 5,000) | SrCl2 | | | Balance | MSA/DBU | 4.5 | 1.2 | 2.5 | 2.1 |
| 1-54 | 0.5% | 0.1% | | | | | | | | |
| Example | PAA (MW of 5,000) | SrCl2 | | | Balance | MSA/DBU | 4.5 | 1.2 | 2.5 | 2.1 |
| 1-55 | 0.5% | 0.1% | | | | | | | | |
| Example | PAA (MW of 5,000) | SrCl2 | | | Balance | MSA/DBU | 4.5 | 1.2 | 2.5 | 2.1 |
| 1-56 | 0.5% | 0.1% | | | | | | | | |
| Example | PAA (MW of 5,000) | SrCl2 | | | Balance | MSA/DBU | 4.5 | 0.15 | 2.2 | 1.6 |
| 1-57 | 0.5% | 0.1% | | | | | | | | |
| Example | PAA (MW of 5,000) | SrCl2 | | | Balance | MSA/DBU | 4.5 | 0.15 | 1.6 | 1.2 |
| 1-58 | 0.5% | 0.1% | | | | | | | | |
| Example | PAA (MW of 5,000) | SrCl2 | | | Balance | MSA/DBU | 4.5 | 0.15 | 2.0 | 1.4 |
| 1-59 | 0.5% | 0.1% | | | | | | | | |
| Example | PAA (MW of 5,000) | SrCl2 | | | Balance | MSA/DBU | 4.5 | 0.15 | 2.0 | 1.4 |
| 1-60 | 0.5% | 0.1% | | | | | | | | |
| Example | PAA (MW of 5,000) | SrCl2 | | | Balance | MSA/DBU | 4.5 | 0.15 | 2.0 | 1.4 |
| 1-61 | 0.5% | 0.1% | | | | | | | | |
| Example | PAA (MW of 5,000) | SrCl2 | | | Balance | MSA/DBU | 4.5 | 0.15 | 2.1 | 1.5 |
| 1-62 | 0.5% | 0.1% | | | | | | | | |
| Example | PAA (MW of 5,000) | SrCl2 | | | Balance | MSA/DBU | 4.5 | 0.15 | 1.6 | 1.1 |
| 1-63 | 0.5% | 0.1% | | | | | | | | |
| Example | PAA (MW of 5,000) | SrCl2 | | | Balance | MSA/DBU | 4.5 | 0.15 | 2.0 | 1.4 |
| 1-64 | 0.5% | 0.1% | | | | | | | | |
| Example | PAA (MW of 5,000) | SrCl2 | | | Balance | MSA/DBU | 4.5 | 0.15 | 2.0 | 1.4 |
| 1-65 | 0.5% | 0.1% | | | | | | | | |
| Example | PAA (MW of 5,000) | SrCl2 | | | Balance | MSA/DBU | 4.5 | 0.15 | 2.0 | 1.4 |
| 1-66 | 0.5% | 0.1% | | | | | | | | |
| Example | PAA (MW of 5,000) | SrCl2 | | | Balance | MSA/DBU | 4.5 | 0.15 | 2.0 | 1.4 |
| 1-67 | 0.5% | 0.1% | | | | | | | | |
| Example | PAA (MW of 5,000) | SrCl2 | | | Balance | MSA/DBU | 4.5 | 0.15 | 2.0 | 1.4 |
| 1-68 | 0.5% | 0.1% | | | | | | | | |
| Example | PAA (MW of 5,000) | SrCl2 | | | Balance | MSA/DBU | 4.5 | 0.15 | 2.0 | 1.4 |
| 1-69 | 0.5% | 0.1% | | | | | | | | |
| Example | PAA (MW of 5,000) | SrCl2 | | | Balance | MSA/DBU | 4.5 | 0.15 | 2.0 | 1.4 |
| 1-70 | 0.5% | 0.1% | | | | | | | | |
| Example | PAA (MW of 5,000) | SrCl2 | | | Balance | MSA/DBU | 4.5 | 0.15 | 2.0 | 1.4 |
| 1-71 | 0.5% | 0.1% | | | | | | | | |
| Example | PAA (MW of 5,000) | SrCl2 | | | Balance | MSA/DBU | 4.5 | 0.15 | 2.0 | 1.4 |
| 1-72 | 0.5% | 0.1% | | | | | | | | |
| Example | PAA (MW of 5,000) | SrCl2 | EGBE | | Balance | MSA/DBU | 4.5 | 0.15 | 1.6 | 1.2 |
| 1-73 | 0.5% | 0.1% | 20% | | | | | | | |
| Example | PAA (MW of 5,000) | SrCl2 | EGBE | Nitric acid | Balance | MSA/DBU | 4.5 | 0.15 | 216.0 | 78.0 |
| 1-74 | 0.5% | 0.1% | 50% | 3% | | | | | | |
| Example | PAA (MW of 5,000) | SrCl2 | EGBE | Nitric acid | Balance | MSA/DBU | 4.5 | 0.15 | 185.0 | 58.0 |
| 1-75 | 0.5% | 0.1% | 50% | 1% | | | | | | |
| Example | PAA (MW of 5,000) | SrCl2 | EGBE | Nitric acid | Balance | MSA/DBU | 4.5 | 0.15 | 86.0 | 45.0 |
| 1-76 | 0.5% | 0.1% | 50% | 0.55% | | | | | | |
| Example | PAA (MW of 5,000) | SrCl2 | EGBE | | Balance | MSA/DBU | 4.5 | 0.15 | 1.5 | 1.1 |
| 1-77 | 0.5% | 0.1% | 50% | | | | | | | |

| | Evaluation results | | | | | | | |
|---|---|---|---|---|---|---|---|---|
| | Etching performance (Å/min) | | | | | | | |
| | SiO₂ | SiON | SiOC | AlOx | Al | W | Co | Cu |
| Example 1-1 | >0.5 | >0.5 | >0.5 | 256.0 | 256.0 | >0.5 | 128.3 | 256.0 |
| Example 1-2 | 1.2 | 1.8 | 1.5 | 259.0 | 259.0 | >0.5 | 133.0 | 254.0 |
| Example 1-3 | 0.8 | 1.2 | 1.3 | 248.0 | 248.0 | >0.5 | 145.0 | 249.0 |
| Example 1-4 | >0.5 | >0.5 | >0.5 | 265.0 | 265.0 | >0.5 | 145.0 | 265.0 |
| Example 1-5 | >0.5 | >0.5 | >0.5 | 258.0 | 258.0 | >0.5 | 145.0 | 289.0 |
| Example 1-6 | >0.5 | >0.5 | >0.5 | 258.0 | 258.0 | >0.5 | 145.0 | 289.0 |
| Example 1-7 | 3.8 | 4.2 | 4.5 | 254.0 | 254.0 | >0.5 | 145.0 | 269.0 |
| Example 1-8 | >0.5 | >0.5 | >0.5 | 258.0 | 258.0 | >0.5 | 145.0 | 289.0 |
| Example 1-9 | 2.2 | 2.5 | 2.9 | 258.0 | 258.0 | >0.5 | 145.0 | 289.0 |
| Example 1-10 | 4.8 | 5.5 | 5.6 | 258.0 | 258.0 | >0.5 | 145.0 | 289.0 |
| Example 1-11 | 6.2 | 6.5 | 6.6 | 258.0 | 258.0 | >0.5 | 145.0 | 289.0 |
| Example 1-12 | >0.5 | >0.5 | >0.5 | 316.0 | 316.0 | >0.5 | 145.0 | 258.0 |
| Example 1-13 | >0.5 | >0.5 | >0.5 | 289.0 | 289.0 | >0.5 | 145.0 | 241.0 |
| Example 1-14 | >0.5 | >0.5 | >0.5 | 298.0 | 298.0 | >0.5 | 145.0 | 216.0 |
| Example 1-15 | >0.5 | >0.5 | >0.5 | 256.0 | 256.0 | >0.5 | 128.3 | 256.0 |
| Example 1-16 | 1.2 | 1.5 | 1.9 | 272.0 | 296.0 | >0.5 | 153.0 | 286.0 |
| Example 1-17 | 6.8 | 9.8 | 12.1 | 311.0 | 356.0 | >0.5 | 184.0 | 316.0 |
| Comparative | >0.5 | >0.5 | >0.5 | 10.2 | 12.5 | 1.1 | 3.5 | 4.2 |
| Example 1-1 | | | | | | | | |
| Comparative | 132.0 | 121.3 | 86.3 | 356.0 | 356.0 | 3.5 | 158.0 | 342.0 |
| Example 1-2 | | | | | | | | |
| Example 1-18 | >0.5 | >0.5 | >0.5 | 256.0 | 256.0 | 2.5 | 65.3 | 32.5 |
| Example 1-19 | >0.5 | >0.5 | >0.5 | 256.0 | 256.0 | >0.5 | 4.3 | 6.5 |
| Example 1-20 | >0.5 | >0.5 | >0.5 | 256.0 | 256.0 | >0.5 | 2.3 | >0.5 |
| Example 1-21 | >0.5 | >0.5 | >0.5 | 158.0 | 123.0 | >0.5 | >0.5 | >0.5 |
| Example 1-22 | >0.5 | >0.5 | >0.5 | >0.5 | >0.5 | >0.5 | >0.5 | >0.5 |
| Example 1-23 | 0.6 | >0.5 | >0.5 | 0.8 | 1.0 | >0.5 | >0.5 | >0.5 |
| Example 1-24 | >0.5 | >0.5 | >0.5 | >0.5 | 0.6 | >0.5 | >0.5 | >0.5 |
| Example 1-25 | >0.5 | >0.5 | >0.5 | >0.5 | >0.5 | >0.5 | >0.5 | >0.5 |
| Example 1-26 | >0.5 | >0.5 | >0.5 | >0.5 | >0.5 | >0.5 | >0.5 | >0.5 |
| Example 1-27 | >0.5 | >0.5 | >0.5 | >0.5 | >0.5 | >0.5 | >0.5 | >0.5 |
| Example 1-28 | >0.5 | >0.5 | >0.5 | >0.5 | 0.7 | >0.5 | >0.5 | >0.5 |
| Example 1-29 | >0.5 | >0.5 | >0.5 | 3.1 | 4.2 | >0.5 | >0.5 | >0.5 |
| Example 1-30 | >0.5 | >0.5 | >0.5 | 0.6 | 0.8 | >0.5 | >0.5 | >0.5 |
| Example 1-31 | >0.5 | >0.5 | >0.5 | 0.7 | 0.9 | >0.5 | >0.5 | >0.5 |
| Example 1-32 | >0.5 | >0.5 | >0.5 | 3.9 | 4.5 | >0.5 | >0.5 | >0.5 |
| Example 1-33 | >0.5 | >0.5 | >0.5 | 3.6 | 3.8 | >0.5 | >0.5 | >0.5 |
| Example 1-34 | >0.5 | >0.5 | >0.5 | 1.4 | 1.6 | >0.5 | >0.5 | >0.5 |
| Example 1-35 | >0.5 | >0.5 | >0.5 | 1.2 | 1.3 | >0.5 | >0.5 | >0.5 |
| Example 1-36 | >0.5 | >0.5 | >0.5 | 1.0 | 1.1 | >0.5 | >0.5 | >0.5 |
| Example 1-37 | >0.5 | >0.5 | >0.5 | 1.0 | 1.2 | >0.5 | >0.5 | >0.5 |
| Example 1-38 | >0.5 | >0.5 | >0.5 | 6.3 | 12.3 | >0.5 | >0.5 | >0.5 |
| Example 1-39 | >0.5 | >0.5 | >0.5 | >0.5 | >0.5 | >0.5 | >0.5 | >0.5 |
| Example 1-40 | >0.5 | >0.5 | >0.5 | >0.5 | 0.8 | >0.5 | >0.5 | >0.5 |
| Example 1-41 | >0.5 | >0.5 | >0.5 | >0.5 | >0.5 | >0.5 | >0.5 | >0.5 |
| Example 1-42 | >0.5 | >0.5 | >0.5 | 0.6 | 1.0 | >0.5 | >0.5 | >0.5 |
| Example 1-43 | >0.5 | >0.5 | >0.5 | >0.5 | 0.6 | >0.5 | >0.5 | >0.5 |
| Example 1-44 | >0.5 | >0.5 | >0.5 | >0.5 | 0.7 | >0.5 | >0.5 | >0.5 |
| Example 1-45 | >0.5 | >0.5 | >0.5 | 31.2 | 25.8 | >0.5 | >0.5 | >0.5 |
| Example 1-46 | >0.5 | >0.5 | >0.5 | 24.3 | 28.6 | >0.5 | >0.5 | >0.5 |
| Example | 1.2 | 1.8 | 1.5 | >0.5 | >0.5 | >0.5 | 24.3 | >0.5 |
| 1-47 | | | | | | | | |
| Example | 0.8 | 1.2 | 1.3 | >0.5 | >0.5 | >0.5 | 10.9 | >0.5 |
| 1-48 | | | | | | | | |
| Example | >0.5 | >0.5 | >0.5 | >0.5 | >0.5 | >0.5 | >0.5 | >0.5 |
| 1-49 | | | | | | | | |
| Example | >0.5 | >0.5 | >0.5 | >0.5 | >0.5 | >0.5 | >0.5 | >0.5 |
| 1-50 | | | | | | | | |
| Example | >0.5 | >0.5 | >0.5 | >0.5 | >0.5 | >0.5 | >0.5 | >0.5 |
| 1-51 | | | | | | | | |
| Example | 3.8 | 4.2 | 4.5 | >0.5 | >0.5 | >0.5 | >0.5 | >0.5 |
| 1-52 | | | | | | | | |
| Example | >0.5 | >0.5 | >0.5 | >0.5 | >0.5 | >0.5 | >0.5 | >0.5 |
| 1-53 | | | | | | | | |
| Example | 2.2 | 2.5 | 2.9 | >0.5 | >0.5 | >0.5 | >0.5 | >0.5 |
| 1-54 | | | | | | | | |
| Example | 4.8 | 5.5 | 5.6 | >0.5 | >0.5 | >0.5 | >0.5 | >0.5 |
| 1-55 | | | | | | | | |
| Example | 6.2 | 6.5 | 6.6 | >0.5 | >0.5 | >0.5 | >0.5 | >0.5 |
| 1-56 | | | | | | | | |
| Example | >0.5 | >0.5 | >0.5 | >0.5 | >0.5 | >0.5 | 4.7 | 8.9 |
| 1-57 | | | | | | | | |
| Example | >0.5 | >0.5 | >0.5 | >0.5 | >0.5 | >0.5 | >0.5 | >0.5 |
| 1-58 | | | | | | | | |
| Example | >0.5 | >0.5 | >0.5 | >0.5 | >0.5 | >0.5 | 1.1 | 2.1 |
| 1-59 | | | | | | | | |
| Example | >0.5 | >0.5 | >0.5 | >0.5 | >0.5 | >0.5 | 1.8 | 3.1 |
| 1-60 | | | | | | | | |
| Example | >0.5 | >0.5 | >0.5 | >0.5 | >0.5 | >0.5 | 1.6 | 3.5 |
| 1-61 | | | | | | | | |
| Example | >0.5 | >0.5 | >0.5 | >0.5 | >0.5 | >0.5 | >0.5 | >0.5 |
| 1-62 | | | | | | | | |
| Example | >0.5 | >0.5 | >0.5 | >0.5 | >0.5 | >0.5 | >0.5 | >0.5 |
| 1-63 | | | | | | | | |
| Example | >0.5 | >0.5 | >0.5 | >0.5 | >0.5 | >0.5 | >0.5 | >0.5 |
| 1-64 | | | | | | | | |
| Example | >0.5 | >0.5 | >0.5 | >0.5 | >0.5 | >0.5 | >0.5 | >0.5 |
| 1-65 | | | | | | | | |
| Example | >0.5 | >0.5 | >0.5 | >0.5 | >0.5 | >0.5 | >0.5 | >0.5 |
| 1-66 | | | | | | | | |
| Example | >0.5 | >0.5 | >0.5 | >0.5 | >0.5 | >0.5 | >0.5 | >0.5 |
| 1-67 | | | | | | | | |
| Example | >0.5 | >0.5 | >0.5 | >0.5 | >0.5 | >0.5 | >0.5 | >0.5 |
| 1-68 | | | | | | | | |
| Example | >0.5 | >0.5 | >0.5 | >0.5 | >0.5 | >0.5 | >0.5 | >0.5 |
| 1-69 | | | | | | | | |
| Example | >0.5 | >0.5 | >0.5 | >0.5 | >0.5 | >0.5 | 3.2 | >0.5 |
| 1-70 | | | | | | | | |
| Example | >0.5 | >0.5 | >0.5 | >0.5 | >0.5 | >0.5 | >0.5 | >0.5 |
| 1-71 | | | | | | | | |
| Example | >0.5 | >0.5 | >0.5 | >0.5 | >0.5 | >0.5 | 2.1 | >0.5 |
| 1-72 | | | | | | | | |
| Example | >0.5 | >0.5 | >0.5 | >0.5 | >0.5 | >0.5 | >0.5 | >0.5 |
| 1-73 | | | | | | | | |
| Example | >0.5 | >0.5 | >0.5 | >0.5 | 25.0 | 6.0 | 8.0 | 12.0 |
| 1-74 | | | | | | | | |
| Example | >0.5 | >0.5 | >0.5 | >0.5 | 15.0 | 2.0 | 4.0 | 9.0 |
| 1-75 | | | | | | | | |
| Example | >0.5 | >0.5 | >0.5 | >0.5 | 8.0 | >0.5 | 1.0 | 4.0 |
| 1-76 | | | | | | | | |
| Example | >0.5 | >0.5 | >0.5 | >0.5 | >0.5 | >0.5 | >0.5 | >0.5 |
| 1-77 | | | | | | | | |

As shown in Table 1, it was found that in a case where the treatment liquids of Examples 1-1 to 1-77, containing a fluorine-containing compound and a water-soluble aromatic compound, and having a pH of 5 or less, were used, the removability for the metal hard mask (etching property) was excellent and the etching of the insulating film could be suppressed.

In contrast, it was found that in a case where the treatment liquid of Comparative Example 1-1, not containing a fluorine-containing compound, was used, the removability for the metal hard mask was deteriorated.

In addition, it was found that in a case where the treatment liquid of Comparative Example 1-2, not containing a water-soluble aromatic compound, was used, the etching of the insulating film became noticeable.

### Examples 2-1 to 2-7

<Preparation of Treatment Liquid>

The respective components shown in Table 2 were mixed and stirred such that the total amount of the respective components became 100% by mass, thereby obtaining each of the treatment liquids of Examples 2-1 to 2-7. The components used for the preparation of each of the treatment liquids are as described above.

For each of the treatment liquids of Examples 2-1 to 2-7, the pH was measured in the same manner as in Example 1-1.

[Evaluation Test]

In Examples 2-1 to 2-7, the performance in a case where the treatment liquid was employed as a “washing liquid” used in the removal of the etching residues was confirmed.

<PER Performance>

In the same manner as the evaluation method for “Etching Performance” in Example 1-1 and the like as described above, the post etching residue (PER) performance was evaluated.

<Washing Performance>

A laminate (corresponding to a laminate before the treatment) comprising a third layer (metal layer: Al, W, Co, or Cu), the other layers (etching stop layer: AlOx, where x is 1 to 3), a second layer (insulating film: SiO₂, SiON, or SiOC), and a first layer having predetermined apertures (metal hard mask: TiN or ZrOx, where x is 1 to 3) in this order was formed on a substrate (Si). Using the obtained laminate, plasma etching was carried out with the first layer as a mask, etching of the second layer was performed until the surface of the third layer was exposed to form holes, thereby producing a sample 1 (see FIG. 1). As the cross section of the laminate was confirmed with pictures of a scanning electron microscope (SEM), plasma etching residues were observed on the surface of hole walls.

In addition, according to the following procedure, the washing performance was evaluated. First, each of the treatment liquids was heated to 65° C. and then the laminate was immersed in the treatment liquid for 10 minutes. The states of the residual residues after immersion of the laminate were confirmed by a scanning electron microscope (SEM), and then the washing performance was evaluated in accordance with the following standards.

A: The residues were completely (100%) washed (100% of the residues confirmed with SEM before immersion were removed after immersion).

B: 98% or more and less than 100% of the residues were washed (98% or more and less than 100% of the residues confirmed with SEM before immersion were removed after immersion).

C: 95% or more and less than 98% of the residues were washed (95% or more and less than 98% of the residues confirmed with SEM before immersion were removed after immersion).

D: 90% or more and less than 95% of the residues were washed (90% or more and less than 95% of the residues confirmed with SEM before immersion were removed after immersion).

E: Less than 90% of the residues were washed (less than 90% of the residues confirmed with SEM before immersion were removed after immersion).

<Corrosion Performance>

The laminate after the evaluation test in “Washing Performance” was observed with a transmission electron microscope (TEM) to confirm whether a battery reaction between different metals (excess corrosion) was observed between the metal layers. According to the degrees of corrosion, the corrosion performance was determined. The evaluation standards are as follows.

A: Occurrence of corrosion between different metals cannot be seen.

B: Occurrence of some corrosion between different metals can be seen.

[Evaluation Results]

The above evaluation results are shown in Table 2 below. Further, “>0.5” in the table means a value of greater than 0.5.

TABLE 2

| | | Water- | | | | | | | | | |
|---|---|---|---|---|---|---|---|---|---|---|---|
| | | soluble | | | | | | | | | |
| | Fluorine-containing | aromatic | | Corrosion | Boron-containing | Polymer | Metal | Organic | | | |
| | compound | compound | Surfactant | inhibitor | compound | compound | ion | solvent | Others | Water | pH adjuster |
| Example | HF | Phthalic | | 5-MBTA | Boric acid | PAA | SrCl2 | | | Balance | MSA/DBU |
| 2-1 | 1.2% | acid | | 0.25% | 0.10% | (MW of | 0.1% | | | | |
| | | 8.0% | | | | 5,000) | | | | | |
| | | | | | | 0.5% | | | | | |
| Example | HF | Phthalic | | 5-MBTA | Boric acid | PAA | SrCl2 | EGBE | | Balance | MSA/DBU |
| 2-2 | 1.2% | acid | | 0.25% | 0.10% | (MW of | 0.1% | 5% | | | |
| | | 8.0% | | | | 5,000) | | | | | |
| | | | | | | 0.5% | | | | | |
| Example | HF | Phthalic | | 5-MBTA | Boric acid | PAA | SrCl2 | EGBE | | Balance | MSA/DBU |
| 2-3 | 1.2% | acid | | 0.25% | 0.10% | (MW of | 0.1% | 10% | | | |
| | | 8.0% | | | | 5,000) | | | | | |
| | | | | | | 0.5% | | | | | |
| Example | HF | Phthalic | | 5-MBTA | Boric acid | PAA | SrCl2 | EGBE | | Balance | MSA/DBU |
| 2-4 | 1.2% | acid | | 0.25% | 0.10% | (MW of | 0.1% | 20% | | | |
| | | 8.0% | | | | 5,000) | | | | | |
| | | | | | | 0.5% | | | | | |
| Example | HF | Phthalic | | 5-MBTA | Boric acid | PAA | SrCl2 | EGBE | | Balance | MSA/DBU |
| 2-5 | 1.2% | acid | | 0.25% | 0.10% | (MW of | 0.1% | 50% | | | |
| | | 8.0% | | | | 5,000) | | | | | |
| | | | | | | 0.5% | | | | | |
| Example | HF | Phthalic | | 5-MBTA | Boric acid | PAA | SrCl2 | HG | | Balance | MSA/DBU |
| 2-6 | 1.2% | acid | | 0.25% | 0.10% | (MW of | 0.1% | 10% | | | |
| | | 8.0% | | | | 5,000) | | | | | |
| | | | | | | 0.5% | | | | | |
| Example | HF | Phthalic | | 5-MBTA | Boric acid | PAA | SrCl2 | DEGBE | | Balance | MSA/DBU |
| 2-7 | 1.2% | acid | | 0.25% | 0.10% | (MW of | 0.1% | 10% | | | |
| | | 8.0% | | | | 5,000) | | | | | |
| | | | | | | 0.5% | | | | | |

| | | | Evaluation results | | | | | | | | | | | |
|---|---|---|---|---|---|---|---|---|---|---|---|---|---|---|
| | | | PER performance (Å/min) | | | | | | | | | | | |
| | | | | | | | | Other | | | | | | |
| | | | First layer | | | | | layer | | | | | | |
| | | Content | (metal hard | | Second layer | | | (etching | Third layer | | | | | |
| | | ratio | mask) | | (insulating layer) | | | stop layer) | (metal layer) | | | | Washing | Corrosion |
| | pH | (M1/M2) | TiN | ZrOx | SiO₂ | SiON | SiOC | AlOx | Al | W | Co | Cu | performance | performance |
| Example | 4.5 | 0.15 | 2.0 | 1.4 | >0.5 | >0.5 | >0.5 | >0.5 | >0.5 | >0.5 | >0.5 | >0.5 | C | B |
| 2-1 | | | | | | | | | | | | | | |
| Example | 4.5 | 0.15 | 1.8 | 1.3 | >0.5 | >0.5 | >0.5 | >0.5 | >0.5 | >0.5 | >0.5 | >0.5 | B | A |
| 2-2 | | | | | | | | | | | | | | |
| Example | 4.5 | 0.15 | 1.8 | 1.3 | >0.5 | >0.5 | >0.5 | >0.5 | >0.5 | >0.5 | >0.5 | >0.5 | A | A |
| 2-3 | | | | | | | | | | | | | | |
| Example | 4.5 | 0.15 | 1.6 | 1.2 | >0.5 | >0.5 | >0.5 | >0.5 | >0.5 | >0.5 | >0.5 | >0.5 | A | A |
| 2-4 | | | | | | | | | | | | | | |
| Example | 4.5 | 0.15 | 1.5 | 1.1 | >0.5 | >0.5 | >0.5 | >0.5 | >0.5 | >0.5 | >0.5 | >0.5 | C | B |
| 2-5 | | | | | | | | | | | | | | |
| Example | 4.5 | 0.15 | 1.6 | 1.2 | >0.5 | >0.5 | >0.5 | >0.5 | >0.5 | >0.5 | >0.5 | >0.5 | A | B |
| 2-6 | | | | | | | | | | | | | | |
| Example | 4.5 | 0.15 | 1.7 | 1.2 | >0.5 | >0.5 | >0.5 | >0.5 | >0.5 | >0.5 | >0.5 | >0.5 | A | B |
| 2-7 | | | | | | | | | | | | | | |

As shown in Table 2, it was found that in a case where the treatment liquids of Examples 2-1 to 2-7, containing a fluorine-containing compound and a water-soluble aromatic compound, and having a pH of 5 or less, were used, the removability for the etching residues of the metal hard mask was excellent and the etching of the insulating film could be suppressed.

### Examples 3-1 to 3-5

The treatment liquids of Examples 2-1 to 2-5 were used as the treatment liquids of Examples 3-1 to 3-5 in the following tests.

<Evaluation after Recycling of Treatment Liquid (after Treatment of 25 Sheets) (Recycling Performance)>

The model films or the laminates used in “PER Performance”, “Washing Performance”, and “Corrosion Performance” were evaluated after performing the treatment of 25 sheets with each of the treatment liquids and employed for evaluation of the recyclability.

Specifically, each sheet of the model films or the laminates was treated with no change in the treatment liquids in the procedure and condition adopted in “PER Performance”, “Washing Performance”, and “Corrosion Performance”, and the model films or the laminates after the treatment of the 25^{th} sheet were evaluated as in “PER Performance”, “Washing Performance”, and “Corrosion Performance”.

Evaluation of each performance after the recycling of the treatment liquids (after treatment of 25 sheets) was performed according to the following standards.

A: In various evaluations in “PER Performance”, “Washing Performance”, and “Corrosion Performance”, results which were not different from those in the treatment of the first sheet were obtained.

B: In any one evaluation of “PER Performance”, “Washing Performance”, or “Corrosion Performance”, results showing a little deterioration were obtained, as compared with those from the treatment of the first sheet.

C: In any one evaluation of “PER Performance”, “Washing Performance”, or “Corrosion Performance”, results showing significant deterioration was obtained, as compared with those from the treatment of the first sheet but the practically required performance was satisfied.

D: In any one evaluation of “PER Performance”, “Washing Performance”, or “Corrosion Performance”, results showing significant deterioration was obtained, as compared with those from the treatment of the first sheet and thus, the practically required performance was not satisfied.

<Evaluation of Treatment Liquid after Elapse of 24 Hours (Change over Time)>

The model films or the laminates used in “PER Performance”, “Washing Performance”, and “Corrosion Performance” were treated using each of the treatment liquids after the elapse of 24 hours from the preparation thereof, and a change of the treatment liquid over time was evaluated.

Specifically, the washing liquid was first put into a storage bottle and stored air-tight at 60° C. for 24 hours. Then, the model films or the laminates were treated using the treatment liquids after storage in the procedure and condition adopted in “PER Performance”, “Washing Performance”, and “Corrosion Performance”, and then “PER Performance”, “Washing Performance”, and “Corrosion Performance” were evaluated.

Evaluation of the change of the treatment liquids over time after the elapse of 24 hours was carried out according to the following standards.

A: In various evaluations in “PER Performance”, “Washing Performance”, and “Corrosion Performance”, results which were not different from those before the storage of the treatment liquids were obtained.

B: In any one evaluation of “PER Performance”, “Washing Performance”, or “Corrosion Performance”, results showing a little deterioration were obtained, as compared with those before the storage of the treatment liquids.

C: In any one evaluation of “PER Performance”, “Washing Performance”, or “Corrosion Performance”, results showing significant deterioration were obtained, as compared with those before the storage of the treatment liquids but the practically required performance was satisfied.

D: In any one evaluation of “PER Performance”, “Washing Performance”, or “Corrosion Performance”, results showing significant deterioration were obtained, as compared with those before the storage of the treatment liquids and thus, the practically required performance was not satisfied.

The evaluation results of Examples 3-1 to 3-5 are shown in Table 3.

TABLE 3

| | | Water- | | | | | |
|---|---|---|---|---|---|---|---|
| | Fluorine- | soluble | | | Boron- | | |
| | containing | aromatic | | Corrosion | containing | Polymer | Metal |
| | compound | compound | Surfactant | inhibitor | compound | compound | ion |
| Example | HF | Phthalic acid | | 5-MBTA | Boric acid | PAA (MW of | SrCl2 |
| 3-1 | 1.2% | 8.0% | | 0.25% | 0.10% | 5,000) | 0.1% |
| | | | | | | 0.5% | |
| Example | HF | Phthalic acid | | 5-MBTA | Boric acid | PAA (MW of | SrCl2 |
| 3-2 | 1.2% | 8.0% | | 0.25% | 0.10% | 5,000) | 0.1% |
| | | | | | | 0.5% | |
| Example | HF | Phthalic acid | | 5-MBTA | Boric acid | PAA (MW of | SrCl2 |
| 3-3 | 1.2% | 8.0% | | 0.25% | 0.10% | 5,000) | 0.1% |
| | | | | | | 0.5% | |
| Example | HF | Phthalic acid | | 5-MBTA | Boric acid | PAA (MW of | SrCl2 |
| 3-4 | 1.2% | 8.0% | | 0.25% | 0.10% | 5,000) | 0.1% |
| | | | | | | 0.5% | |
| Example | HF | Phthalic acid | | 5-MBTA | Boric acid | PAA (MW of | SrCl2 |
| 3-5 | 1.2% | 8.0% | | 0.25% | 0.10% | 5,000) | 0.1% |
| | | | | | | 0.5% | |

| | | | | | | | Evaluation results | |
|---|---|---|---|---|---|---|---|---|
| | | | | | | Content | | Change |
| | Organic | | | pH | | ratio | Recycling | over |
| | solvent | Others | Water | adjuster | pH | (M1/M2) | performance | time |
| Example | | | Balance | MSA/DBU | 4.5 | 0.15 | B | B |
| 3-1 | | | | | | | | |
| Example | EGBE | | Balance | MSA/DBU | 4.5 | 0.15 | B | B |
| 3-2 | 5% | | | | | | | |
| Example | EGBE | | Balance | MSA/DBU | 4.5 | 0.15 | A | A |
| 3-3 | 10% | | | | | | | |
| Example | EGBE | | Balance | MSA/DBU | 4.5 | 0.15 | A | A |
| 3-4 | 20% | | | | | | | |
| Example | EGBE | | Balance | MSA/DBU | 4.5 | 0.15 | A | A |
| 3-5 | 50% | | | | | | | |

As shown in Table 3, it was found that the treatment liquids of Examples 3-1 to 3-5 had excellent recyclability and changes over time.

In the same manner as in Example 3-1 except that the evaluation was carried out by changing 8.0% of phthalic acid to 5.0% of phthalic acid and 3.0% of phenylphosphonic acid, the same results as in Example 3-1 were obtained.

In the same manner as in Example 3-1 except that the evaluation was carried out by changing 0.1% of boric acid to 0.05% of boric acid and 0.05% of monophenyl borate, the same results as in Example 3-1 were obtained.

In the same manner as in Example 3-1 except that the evaluation was carried out by changing 0.25% of 5-MBTA to 0.15% of 5-MBTA and 0.1% of IRGAMET42, the same results as in Example 3-1 were obtained.

In the same manner as in Example 3-1 except that the evaluation was carried out by changing 0.1% of SrCl₂ to 0.08% of SrCl₂ and 0.02% of BaCl₂, the same results as in Example 3-1 were obtained.

In the same manner as in Example 3-3 except that the evaluation was carried out by changing 10% of EGBE to 5% of EGBE and 5% of DEGBE, the same results as in Example 3-3 were obtained.

In the same manner as in Example 3-3 except that the evaluation was carried out by changing 0.5% of PAA (MW of 5,000) to 0.4% of PAA (MW of 5,000) and 0.1% of polystyrenesulfonic acid (MW of 3,000), the same results as in Example 3-3 were obtained.

In the same manner as in Example 3-3 except that the evaluation was carried out by changing HF to ammonium fluoride (manufactured by Stella Chemifa Corporation), the same results as in Example 3-3 except that the recycling performance became B were obtained. In addition, with regard to the etching performance and the PER performance, the same results were obtained.

In the same manner as in Example 3-3 except that the evaluation was carried out by changing HF to ammonium hexafluorosilicate (manufactured by Stella Chemifa Corporation), the same results as in Example 3-3 except that the recycling performance became B were obtained. In addition, with regard to the etching performance and the PER performance, the same results were obtained.

In the same manner as in Example 3-3 except that the evaluation was carried out by changing 1.2% of HF to 0.8% of HF and 0.4% of ammonium fluoride, the same results as in Example 3-3 were obtained. In addition, with regard to the etching performance and the PER performance, the same results were obtained.

### EXPLANATION OF REFERENCES

1: substrate
2: metal layer
3 etching stop layer
4: interlayer insulating film
5: metal hard mask
6: hole
10: laminate
11: inner wall
11a: cross-sectional wall
11b: bottom wall
12: dry etching residue

What is claimed is:

1. A treatment liquid for a semiconductor device, comprising:
a fluorine-containing compound; and
a water-soluble aromatic compound not having a heterocyclic group but having a benzene ring,
wherein the treatment liquid has a pH of 5 or less.

2. The treatment liquid according to claim 1,
wherein a pKa of the water-soluble aromatic compound is 6 or less.

3. The treatment liquid according to claim 1, further comprising water,
wherein a content of water is 50% by mass or more with respect to the total mass of the treatment liquid.

4. The treatment liquid according to claim 1,
wherein the treatment liquid does not comprise an oxidizing agent.

5. The treatment liquid according to claim 1,
wherein the fluorine-containing compound is hydrogen fluoride.

6. The treatment liquid according to claim 1,
wherein the water-soluble aromatic compound has an acidic group.

7. The treatment liquid according to claim 1,
wherein the water-soluble aromatic compound includes at least one selected from the group consisting of phenylphosphonic acid, benzenecarboxylic acid, benzenesulfonic acid, and derivatives thereof.

8. The treatment liquid according to claim 1,
wherein a content of the water-soluble aromatic compound is 0.05% to 10% by mass with respect to the total mass of the treatment liquid.

9. The treatment liquid according to claim 1,
wherein in a case where a content of the fluorine-containing compound and a content of the water-soluble aromatic compound are defined as M1 and M2 respectively, a content ratio M1/M2 is 0.05 to 10.

10. The treatment liquid according to claim 1,
wherein the pH is 2 to 5.

11. The treatment liquid according to claim 1, further comprising an anionic surfactant.

12. The treatment liquid according to claim 1, further comprising a corrosion inhibitor.

13. The treatment liquid according to claim 1, further comprising a boron-containing compound.

14. The treatment liquid according to claim 1, further comprising an organic solvent.

15. The treatment liquid according to claim 1, further comprising an anionic polymer.

16. The treatment liquid according to claim 15,
wherein a weight-average molecular weight of the anionic polymer is 2,000 to 100,000.

17. The treatment liquid according to claim 15,
wherein the anionic polymer is a polyacrylic acid.

18. The treatment liquid according to claim 1, further comprising a metal ion.

19. The treatment liquid according to claim 18,
wherein the metal ion is a divalent or higher metal ion.

20. The treatment liquid according to claim 18,
wherein the metal ion is at least one selected from the group consisting of an alkaline earth metal ion and an Al ion.

21. The treatment liquid according to claim 18,
wherein the metal ion is at least one selected from the group consisting of a Sr ion, a Ba ion, and an Al ion.

22. The treatment liquid according to claim 1,
wherein the semiconductor device has a laminate for a semiconductor device, the laminate comprising a substrate, a second layer formed on the substrate, and a first layer formed on the second layer,
the second layer includes at least one material selected from the group consisting of SiOx, SiOC, SiN, and SiON, where x is a number represented by 1 to 3, and the first layer is formed of materials other than those of the second layer, and
the treatment liquid is used for a treatment of the laminate.

23. The treatment liquid according to claim 22,
wherein the first layer includes at least one material selected from the group consisting of TiN, TiOx, and ZrOx, where x is a number represented by 1 to 3.

24. The treatment liquid according to claim 22,
wherein in a case where a removal rate of the first layer by the treatment liquid and a removal rate of the second layer by the treatment liquid are defined as ER1 and ER2 respectively, a removal rate ratio ER1/ER2 is 0.5 to 1,000.

25. The treatment liquid according to claim 22,
wherein the laminate further comprises a third layer between the substrate and the second layer, and
the third layer is a metal including at least one material selected from the group consisting of W, Co, Cu, and Al.

26. A method for treating a laminate, comprising a treating step B of subjecting a laminate for a semiconductor device to a treatment, using the treatment liquid according to claim 1, the laminate comprising a substrate, a second layer formed on the substrate, and a first layer formed on the second layer,
wherein the first layer includes at least one material selected from the group consisting of TiN, TiOx, and ZrOx, and
the second layer includes at least one material selected from the group consisting of SiOx, SiOC, SiN, and SiON, where x is a number represented by 1 to 3.

27. The method for treating a laminate according to claim 26, further comprising a treatment liquid preparing step A of preparing the treatment liquid before the treating step B.
